(19) United States
(12) Patent Application Publication
(10) Pub. No.: US 2021/0359014 A1
(43) Pub. Date: Nov. 18, 2021

(54) ELECTRO-OPTICAL DEVICE AND ELECTRONIC APPARATUS

(71) Applicant: SEIKO EPSON CORPORATION, Tokyo (JP)

(72) Inventors: Takeshi Koshihara, Matsumoto-shi (JP); Jun Irobe, Chino-shi (JP)

(73) Assignee: SEIKO EPSON CORPORATION, Tokyo (JP)

(21) Appl. No.: 17/316,741

(22) Filed: May 11, 2021

(30) Foreign Application Priority Data
May 12, 2020 (JP) 2020-083829

(51) Int. Cl. H01L 27/32

(52) U.S. Cl. CPC H01L 27/322; H01L 27/3218

(57) ABSTRACT

An electro-optical device includes a first light-emitting element configured to emit light in a first wavelength region, a second light-emitting element configured to emit light in a second wavelength region different from the first wavelength region, a third light-emitting element configured to emit light in a third wavelength region different from the second wavelength region, a first filter configured to transmit light in the first wavelength region and light in the third wavelength region and absorb light in the second wavelength region, and a second filter configured to transmit light in the second wavelength region and light in the third wavelength region and absorb light in the first wavelength region, in which the third light-emitting element has a portion overlapping the first filter and a portion overlapping the second filter in plan view.

The present application is based on, and claims priority from JP Application Serial Number 2020-083829, filed May 12, 2020, the disclosure of which is hereby incorporated by reference herein in its entirety.

### BACKGROUND

### 1. Technical Field

The present disclosure relates to an electro-optical device and an electronic apparatus.

### 2. Related Art

An electro-optical device including light-emitting elements such as organic electroluminescence (EL) elements are known. As disclosed in JP-A-2019-117941, this type of device includes, for example, a color filter that transmits light in a predetermined wavelength region from light emitted from a light-emitting element.

The device described in JP-A-2019-117941 includes a plurality of sub-pixels each including a light-emitting element, and a plurality of color filters corresponding to each sub-pixel. Specifically, a red color filter is arranged to overlap a light-emitting element capable of emitting red light, a green color filter is arranged to overlap a light-emitting element capable of emitting green light, and a blue color filter is arranged to overlap a light-emitting element capable of emitting blue light.

In the device described in JP-A-2019-117941, the color filter corresponding to the light in the wavelength region emitted from the light-emitting element is arranged for each sub-pixel. Consequently, in the device, when the width of the sub-pixel becomes small or the density of the sub-pixel becomes high, the visual field angle characteristics may be reduced.

### SUMMARY

One aspect of an electro-optical device according to the present disclosure includes a first light-emitting element configured to emit light in a first wavelength region, a second light-emitting element configured to emit light in a second wavelength wavelength region different from the first wavelength region, a third light-emitting element configured to emit light in a third wavelength region different from the second wavelength region, a first filter configured to transmit light in the first wavelength region and light in the third wavelength region and absorb light in the second wavelength region, and a second filter configured to transmit light in the second wavelength region and light in the third wavelength region and absorb light in the first wavelength region, in which the third light-emitting element has a portion overlapping the first filter and a portion overlapping the second filter in plan view.

One aspect of an electronic apparatus according to the present disclosure includes the above-described electro-optical device and a control unit configured to control operation of the electro-optical device.

### BRIEF DESCRIPTION OF THE DRAWINGS

FIG. 1 is a plan view schematically illustrating an electro-optical device according to a first embodiment.

FIG. 2 is an equivalent circuit diagram of a sub-pixel according to the first embodiment.

FIG. 3 is a diagram illustrating a cross section taken along line A1-A1 of FIG. 1.

FIG. 4 is a diagram illustrating a cross section taken along line A2-A2 of FIG. 1.

FIG. 5 is a schematic plan view illustrating a part of a light-emitting element layer according to the first embodiment.

FIG. 6 is a schematic plan view illustrating a part of a color filter according to the first embodiment.

FIG. 7 is a schematic plan view illustrating an arrangement of the light-emitting element layer and the color filter according to the first embodiment.

FIG. 8 is a diagram for explaining characteristics of a magenta filter.

FIG. 9 is a diagram for explaining characteristics of a cyan filter.

FIG. 10 is a diagram for explaining characteristics of the color filter according to the first embodiment.

FIG. 11 is a schematic diagram illustrating an electro-optical device including a known color filter.

FIG. 12 is a schematic diagram illustrating an example when the electro-optical device of FIG. 11 is miniaturized.

FIG. 13 is a schematic diagram illustrating the electro-optical device according to the first embodiment.

FIG. 14 is a schematic plan view illustrating an arrangement of a light-emitting element layer and a color filter according to a second embodiment.

FIG. 15 is a diagram for explaining characteristics of a yellow filter.

FIG. 16 is a diagram for explaining characteristics of a color filter according to the second embodiment.

FIG. 17 is a schematic plan view illustrating an arrangement of a light-emitting element layer and a color filter according to a third embodiment.

FIG. 18 is a diagram for explaining characteristics of the color filter according to the third embodiment.

FIG. 19 is a schematic plan view illustrating a part of a light-emitting element layer according to a fourth embodiment.

FIG. 20 is a schematic plan view illustrating a part of a color filter according to the fourth embodiment.

FIG. 21 is a schematic plan view illustrating an arrangement of the light-emitting element layer and the color filter according to the fourth embodiment.

FIG. 22 is a schematic plan view illustrating an arrangement of a light-emitting element layer and a color filter according to a fifth embodiment.

FIG. 23 is a schematic plan view illustrating an arrangement of a light-emitting element layer and a color filter according to a sixth embodiment.

FIG. 24 is a plan view schematically illustrating a part of a virtual image display device as an example of an electronic apparatus.

FIG. 25 is a perspective view illustrating a personal computer as an example of the electronic apparatus.

### DESCRIPTION OF EXEMPLARY EMBODIMENTS

Preferred embodiments of the present disclosure will be described below with reference to the accompanying drawings. Note that, in the drawings, dimensions and scales of components are different from actual dimensions and scales as appropriate, and some of the components are schematically illustrated to make them easily recognizable. Further, the scope of the present disclosure is not limited to these embodiments unless otherwise stated to limit the present disclosure in the following descriptions.

### 1. Electro-Optical Device 100

### 1A. First Embodiment

1A-1. Configuration of Electro-Optical Device 100

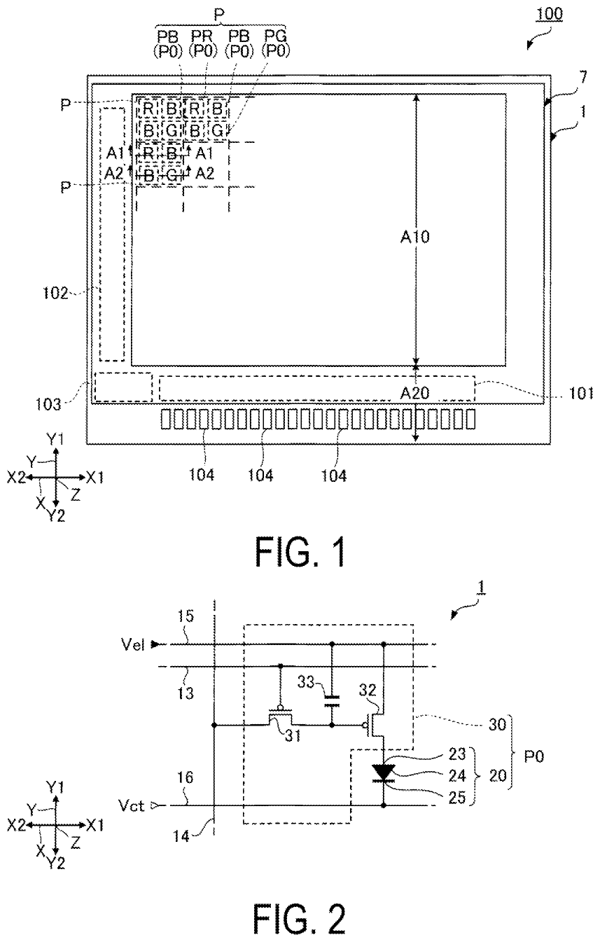

FIG. 1 is a plan view schematically illustrating an electro-optical device 100 according to a first embodiment. Note that, in the following, for convenience of explanation, the description will be made appropriately using an X-axis, a Y-axis, and a Z-axis orthogonal to each other. Further, one direction along the X-axis is defined as an X1 direction, and a direction opposite to the X1 direction is defined as an X2 direction. Similarly, one direction along the Y-axis is defined as a Y1 direction, and a direction opposite to the Y1 direction is defined as a Y2 direction. One direction along the Z-axis is defined as a Z1 direction, and a direction opposite to the Z1 direction is defined as a Z2 direction. A plane including the X-axis and the Y-axis is defined as an X-Y plane. Additionally, the view from the Z1 direction or the Z2 direction is defined as “plan view”.

The electro-optical device 100 illustrated in FIG. 1 is a device that displays a full color image using an organic electroluminescence (EL). Note that the image includes an image that displays only character information. The electro-optical device 100 is a microdisplay preferably used for, for example, a head-mounted display.

The electro-optical device 100 has a display area A10 in which an image is displayed, and a peripheral area A20 surrounding the display area A10 in plan view. In the example illustrated in FIG. FIG. 1, the shape of the display area A10 in plan view is quadrangular, but the shape is not limited thereto, and other shapes may be used.

The display area A10 has a plurality of pixels P. Each pixel P is the smallest unit for displaying image. In this embodiment, the plurality of pixels P are arranged in a matrix in the X1 direction and the Y2 direction. Each pixel P has a sub-pixel PR capable of obtaining light in a red wavelength region, a sub-pixel PG capable of obtaining light in a green wavelength region, and two sub-pixels PB capable of obtaining light in a blue wavelength region. Sub-pixels PB, a sub-pixel PG, and a sub-pixel PR constitute one pixel P. In the following, when the sub-pixel PB, the sub-pixel PG, and the sub-pixel PR are not distinguished, they are expressed as the sub-pixel P0.

The sub-pixel P0 is one of elements that constitute the pixel P. The sub-pixel P0 is the smallest unit that is independently controlled. The sub-pixel P0 is controlled independently of other sub-pixels P0. The plurality of sub-pixels P0 are arranged in a matrix in the X1 direction and the Y2 direction. Further, in this embodiment, the array of the sub-pixels P0 is a Bayer array. The Bayer array is an array in which one sub-pixel PR, one sub-pixel PG, and two sub-pixels PB constitute one pixel P. In the Bayer array, the two sub-pixels PB are arranged obliquely for the array direction of the pixels P.

Here, any one of the blue wavelength region, the green wavelength region, and the red wavelength region corresponds to a “first wavelength region”. One other corresponds to a “second wavelength region”. The remaining one corresponds to a “third wavelength region”. Note that the “first wavelength region”, the “second wavelength region”, and the “third wavelength region” are different wavelength regions from each other. In this embodiment, an example will be described in which the red wavelength region is defined as the “first wavelength region”, the green wavelength region is defined as the “second wavelength region”, and the blue wavelength region is defined as the “third wavelength region”. Note that the blue wavelength region is a wavelength region having shorter wavelengths than the green wavelength region, and the green wavelength region is a wavelength region having shorter wavelengths than the red wavelength region.

Further, the electro-optical device 100 includes an element substrate 1 and a transmissive substrate 7 having optical transparency. The electro-optical device 100 has a so-called top emission structure, and emits light from the transmissive substrate 7. Note that the direction in which the element substrate 1 and the transmissive substrate 7 overlap is the same as the Z1 direction or the Z2 direction. Further, the optical transparency means transparency to visible light, and preferably means that the transmittance of visible light is equal to 50% or greater.

The element substrate 1 includes a data line driving circuit 101, a scanning line drive circuit 102, a control circuit 103, and a plurality of external terminals 104. The data line driving circuit 101, the scanning line drive circuit 102, the control circuit 103, and the plurality of external terminals 104 are disposed in the peripheral area A20. The data line driving circuit 101 and the scanning line drive circuit 102 are peripheral circuits that control the driving of each of a plurality of components constituting the sub-pixel P0. The control circuit 103 controls display of an image. Image data is supplied to the control circuit 103 from an upper circuit (not illustrated). The control circuit 103 supplies various signals based on the image data to the data line driving circuit 101 and the scanning line drive circuit 102. Although not illustrated, a flexible printed circuit (FPC) board or the like for electrically coupling to the upper circuit is coupled to the external terminal 104. Further, a power supply circuit (not illustrated) is electrically coupled to the element substrate 1.

The transmissive substrate 7 is a cover that protects a light-emitting element 20 and a color filter 5, which are described later, included in the element substrate 1. The transmissive substrate 7 is composed of, for example, a glass substrate or a quartz substrate.

FIG. 2 is an equivalent circuit diagram of the sub-pixel P0 illustrated in FIG. 1. The element substrate 1 is provided with a plurality of scanning lines 13, a plurality of data lines 14, a plurality of power supplying lines 15, and a plurality of power supplying lines 16. In FIG. 2, one sub-pixel P0 and the corresponding elements are typically illustrated.

The scanning line 13 extends in the X1 direction and the data line 14 extends in the Y2 direction. Note that, although not illustrated, the plurality of scanning lines 13 and the plurality of data lines 14 are arranged in a grid pattern. Further, the scanning lines 13 are coupled to the scanning line drive circuit 102 illustrated in FIG. 1, and the data lines 14 are coupled to the data line driving circuit 101 illustrated in FIG. 1.

As illustrated in FIG. 2, the sub-pixel P0 includes the light-emitting element 20 and a pixel circuit 30 that controls driving of the light-emitting element 20. The light-emitting element 20 is constituted of an organic light emitting diode (OLED). The light-emitting element 20 includes a pixel electrode 23, a common electrode 25, and an organic layer 24.

The power supplying line 15 is electrically coupled to the pixel electrode 23 via the pixel circuit 30. On the other hand, the power supplying line 16 is electrically coupled to the common electrode 25. Here, a power supply potential Vel on a high potential side is supplied from the power supply circuit (not illustrated) to the power supplying line 15. A power supply potential Vct on a low potential side is supplied from the power supply circuit (not illustrated) to the power supplying line 16. The pixel electrode 23 functions as an anode, and the common electrode 25 functions as a cathode. In the light-emitting element 20, the holes supplied from the pixel electrode 23 and the electrons supplied from the common electrode 25 are recombined in the organic layer 24, so that the organic layer 24 emits light. Note that the pixel electrode 23 is provided for each sub-pixel P0, and the pixel electrode 23 is controlled independently of the other pixel electrodes 23.

The pixel circuit 30 includes a switching transistor 31, a driving transistor 32, and a retention capacitor 33. Agate of the switching transistor 31 is electrically coupled to the scanning line 13. Further, one of a source and a drain of the switching transistor 31 is electrically coupled to the data line 14, and the other is electrically coupled to a gate of the driving transistor 32. Further, one of a source and a drain of the driving transistor 32 is electrically coupled to the power supplying line 15, and the other is electrically coupled to the pixel electrode 23. Further, one of electrodes of the retention capacitor 33 is coupled to the gate of the driving transistor 32, and another electrode is coupled to the power supplying line 15.

In the pixel circuit 30 described above, when the scanning line 13 is selected by the scanning line drive circuit 102 activating the scanning signal, the switching transistor 31 provided in the selected sub-pixel P0 is turned on. Then, the data signal is supplied from the data line 14 to the driving transistor 32 corresponding to the selected scanning line 13. The driving transistor 32 supplies a current corresponding to a potential of the supplied data signal, that is, a current corresponding to a potential difference between the gate and the source, to the light-emitting element 20. Then, the light-emitting element 20 emits light at luminance corresponding to the magnitude of the current supplied from the driving transistor 32. Further, when the scanning line drive circuit 102 releases the selection of the scanning line 13 and the switching transistor 31 is turned off, the potential of the gate of the driving transistor 32 is held by the retention capacitor 33. Consequently, the light-emitting element 20 can hold the light emission of the light-emitting element 20 even after the switching transistor 31 is turned off.

Note that the configuration of the pixel circuit 30 described above is not limited to the illustrated configuration. For example, the pixel circuit 30 may further include a transistor that controls the conduction between the pixel electrode 23 and the driving transistor 32.

1A-2. Element Substrate 1

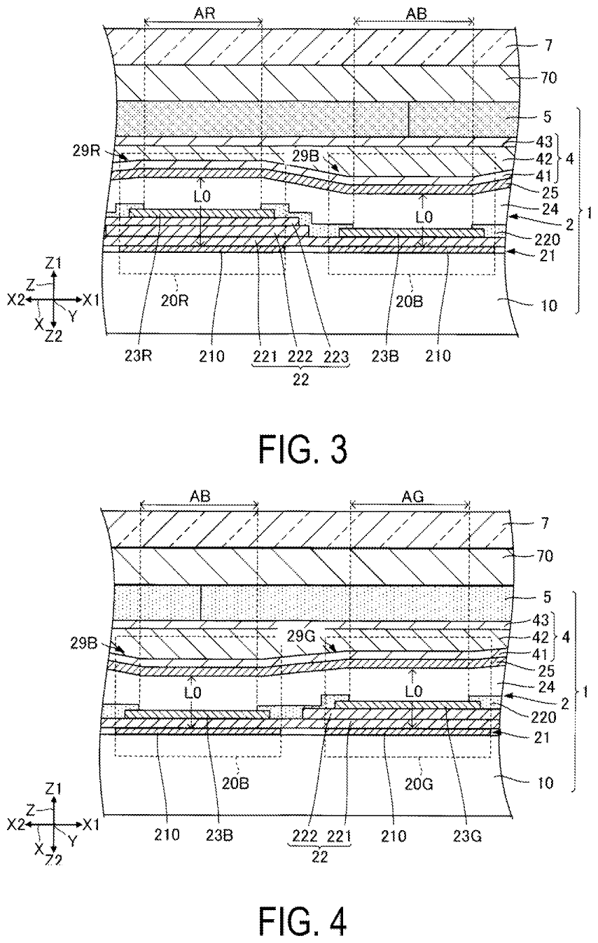

FIG. 3 is a diagram illustrating a cross section taken along line A1-A1 of FIG. 1. FIG. 4 is a diagram illustrating a cross section taken along line A2-A2 of FIG. 1. The following description will be described with the Z1 direction as the upper side and the Z2 direction as the lower side. In the following, a “B” is added to the ends of the reference signs for the elements associated with the sub-pixel PB, a “G” is added to the ends of the reference signs for the elements associated with the sub-pixel PG, and an “R” is added to the ends of the reference signs for the elements associated with the sub-pixel PR. Note that when no distinction is made for each emission color, the “B”, “G”, and “R” at the ends of the reference signs are omitted.

As illustrated in FIGS. 3 and 4, the element substrate 1 includes a substrate 10, a reflection layer 21, a light-emitting element layer 2, a protective layer 4, and the color filter 5. Note that the above-mentioned transmissive substrate 7 is bonded to the element substrate 1 by an adhesive layer 70.

Although not illustrated in detail, the substrate 10 is a wiring substrate in which the above-mentioned pixel circuit 30 is formed at, for example, a silicon substrate. Note that, instead of the silicon substrate, for example, a glass substrate, a resin substrate, or a ceramic substrate may be used. Further, although not illustrated in detail, each of the above-mentioned transistors included in the pixel circuit 30 may be a MOS transistor, a thin film transistor, or a field effect transistor. When the transistor included in the pixel circuit 30 is a MOS transistor having an active layer, the active layer may be constituted of a silicon substrate. Further, examples of the materials for each element and various wirings of the pixel circuit 30 include conductive materials such as polysilicon, metal, metal silicide, and metallic compounds.

The reflection layer 21 is disposed on the substrate 10. The reflection layer 21 includes a plurality of reflection sections 210 having light reflectivity. The light reflectivity means reflectivity to visible light, and preferably means that the reflectance of visible light is equal to 50% or greater. Each reflection section 210 reflects light generated in the organic layer 24. Note that, although not illustrated, the plurality of reflection sections 210 are arranged in a matrix corresponding to the plurality of sub-pixels P0 in plan view. Examples of the material of the reflection layer 21 include metals such as aluminum (Al) and silver (Ag), or alloys of these metals. Note that the reflection layer 21 may function as wiring that is electrically coupled to the pixel circuit 30. Further, the reflection layer 21 may be regarded as a part of the light-emitting element layer 2.

The light-emitting element layer 2 is disposed on the reflection layer 21. The light-emitting element layer 2 is a layer in which the plurality of light-emitting elements 20 are provided. Further, the light-emitting element layer 2 includes an insulating layer 22, an element separation layer 220, the plurality of pixel electrodes 23, the organic layer 24, and the common electrode 25. The insulating layer 22, the element separation layer 220, the organic layer 24, and the common electrode 25 are common to the plurality of light-emitting elements 20.

The insulating layer 22 is a distance adjusting layer that adjusts an optical distance L0, which is an optical distance between the reflection section 210 and the common electrode 25 described later. The insulating layer 22 is composed of a plurality of films having insulating properties. Specifically, the insulating layer 22 includes a first insulating film 221, a second insulating film 222, and a third insulating film 223. The first insulating film 221 covers the reflection layer 21. The first insulating film 221 is formed in common with the pixel electrodes 23B, 23G, and 23R. The second insulating film 222 is disposed on the first insulating film 221. The second insulating film 222 overlaps the pixel electrodes 23R and 23G in plan view, and does not overlap the pixel electrode 23B in plan view. The third insulating film 223 is disposed on the second insulating film 222. The third insulating film 223 overlaps the pixel electrode 23R in plan view, and does not overlap the pixel electrodes 23B and 23G in plan view.

The element separation layer 220 having a plurality of openings is disposed on the insulating layer 22. The element separation layer 220 covers each of the outer edges of the plurality of pixel electrodes 23. A plurality of light-emitting regions A are defined by the plurality of openings of the element separation layer 220. Specifically, a light-emitting region AR of a light-emitting element 20R, a light-emitting region AG of a light-emitting element 20G, and a light-emitting region AB of a light-emitting element 20B are defined.

Examples of the materials of the insulating layer 22 and the element separation layer 220 include silicon-based inorganic materials such as silicon oxide and silicon nitride. Note that in the insulating layer 22 illustrated in FIG. 3, the third insulating film 223 is disposed on the second insulating film 222, but, for example, the second insulating film 222 may be disposed on the third insulating film 223.

The plurality of pixel electrodes 23 are disposed on the insulating layer 22. The plurality of pixel electrodes 23 are provided one-to-one for the plurality of sub-pixels P0. Although not illustrated, each pixel electrode 23 overlaps the corresponding reflection section 210 in plan view. Each pixel electrode 23 has optical transparency and electrical conductivity. Examples of the material of the pixel electrode 23 include transparent conductive materials such as indium tin oxide (ITO) and indium zinc oxide (IZO). The plurality of pixel electrodes 23 are electrically isolated from each other by the element separation layer 220.

The organic layer 24 is disposed on the plurality of pixel electrodes 23. The organic layer 24 includes a light-emitting layer containing an organic light-emitting material. The organic light-emitting material is a light-emitting organic compound. In addition to the light-emitting layer, the organic layer 24 includes, for example, a hole injection layer, a hole transport layer, an electron transport layer, and an electron injection layer. The organic layer 24 achieves white light emission by including a light-emitting layer capable of obtaining each of blue, green, and red light emission colors. Note that the configuration of the organic layer 24 is not particularly limited to the above-mentioned configuration, and a known configuration can be applied.

On the organic layer 24, the common electrode 25 is disposed. The common electrode 25 is disposed on the organic layer 24. The common electrode 25 has light reflectivity, optical transparency, and electrical conductivity. The common electrode 25 is formed of, for example, an alloy containing Ag such as MgAg.

In the above light-emitting element layer 2, the light-emitting element 20R includes the first insulating film 221, the second insulating film 222, the third insulating film 223, the element separation layer 220, the pixel electrode 23R, the organic layer 24, and the common electrode 25. The light-emitting element 20G includes the first insulating film 221, the second insulating film 222, the element separation layer 220, the pixel electrode 23G, the organic layer 24, and the common electrode 25. The light-emitting element 20B includes the first insulating film 221, the element separation layer 220, the pixel electrode 23B, the organic layer 24, and the common electrode 25. Note that each of the light-emitting elements 20 may be regarded as including the reflection section 210.

Here, the optical distance L0 between the reflection layer 21 and the common electrode 25 is different for each sub-pixel P0. Specifically, the optical distance L0 of the sub-pixel PR is set corresponding to the red wavelength region. The optical distance L0 of the sub-pixel PG is set corresponding to the green wavelength region. The optical distance L0 of the sub-pixel PB is set corresponding to the blue wavelength region.

Therefore, each light-emitting element 20 has an optical resonance structure 29 that resonates light in a predetermined wavelength region between the reflection layer 21 and the common electrode 25. The light-emitting elements 20R, 20G, and 20B have different optical resonance structures 29 from each other. In the optical resonance structure, the light generated in the light-emitting layer of the organic layer 24 is multiple reflected between the reflection layer 21 and the common electrode 25, and light in the predetermined wavelength region is selectively enhanced. The light-emitting element 20R has an optical resonance structure 29R that enhances light in the red wavelength region between the reflection layer 21 and the common electrode 25. The light-emitting element 20G has an optical resonance structure 29G that enhances light in the green wavelength region between the reflection layer 21 and the common electrode 25. The light-emitting element 20B has an optical resonance structure 29B that enhances light in the blue wavelength region between the reflection layer 21 and the common electrode 25.

The resonance wavelength in the optical resonance structure 29 is determined by the optical distance L0. When the resonance wavelength is λ0, the following relationship [1] holds true. Note that Φ (radian) in the relationship [1] represents the sum of the phase shifts that occur during transmission and reflection between the reflection layer 21 and the common electrode 25.

{(2×L0)/λ0+Φ}/(2π)=m0 (m0 is an integer) [1]

The optical distance L0 is set so that a peak wavelength of light in a wavelength region to be extracted is the wavelength λ0. With this setting, light in the predetermined wavelength region to be extracted is enhanced, and the light can be increased in intensity and a spectrum of the light can be narrowed.

In this embodiment, as described above, the optical distance L0 is adjusted by making the thickness of the insulating layer 22 different for each of the sub-pixels PB, PG, and PR. Note that the method for adjusting the optical distance L0 is not limited to the method for adjusting the thickness of the insulating layer 22. For example, the optical distance L0 may be adjusted by making the thickness of the pixel electrode 23 different for each of the sub-pixels PB, PG, and PR.

The protective layer 4 is disposed on the plurality of light-emitting elements 20. The protective layer 4 protects the plurality of light-emitting elements 20. Specifically, the protective layer 4 seals the plurality of light-emitting elements 20 in order to protect the plurality of light-emitting elements 20 from the outside. The protective layer 4 has gas barrier properties, and, for example, protects each light-emitting element 20 from external moisture, oxygen, or the like. By providing the protective layer 4, deterioration of the light-emitting element 20 can be suppressed as compared with a case in which the protective layer 4 is not provided. Consequently, quality and reliability of the electro-optical device 100 can be improved. Note that since the electro-optical device 100 has the top emission structure, the protective layer 4 has optical transparency.

The protective layer 4 includes a first layer 41, a second layer 42, and a third layer 43. The first layer 41, the second layer 42, and the third layer 43 are layered in this order in a direction away from the light-emitting element layer 2. The first layer 41, the second layer 42, and the third layer 43 have insulating properties. The material of the first layer 41 and the third layer 43 is, for example, an inorganic compound such as silicon oxynitride (SiON). The second layer 42 is a layer for providing a flat surface to the third layer 43. The material of the second layer 42 is, for example, a resin such as an epoxy resin or an inorganic compound.

The color filter 5 selectively transmits light in a predetermined wavelength region. The predetermined wavelength region includes the peak wavelength λ0 determined by the above-mentioned optical distance L0. By using the color filter 5, the color purity of light emitted from each sub-pixel P0 can be increased as compared with a case in which the color filter 5 is not used. The color filter 5 is formed of a resin material such as an acrylic photosensitive resin material containing a color material, for example. The color material is pigment or dye. The color filter 5 is formed using, for example, a spin coating method, a printing method, or an ink jet method.

The transmissive substrate 7 is bonded onto the element substrate 1 via the adhesive layer 70. The adhesive layer 70 is a transparent adhesive using a resin material such as an epoxy resin or an acrylic resin.

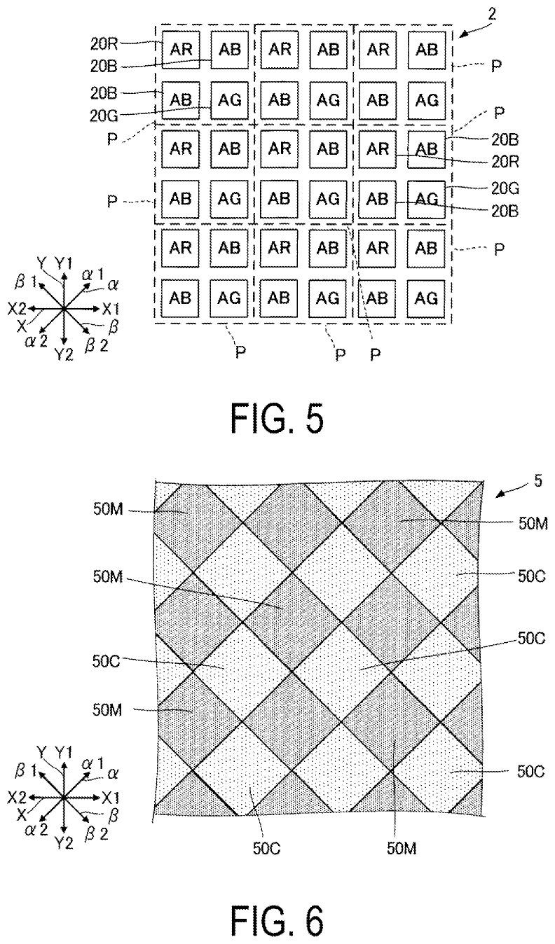

FIG. 5 is a schematic plan view illustrating a part of the light-emitting element layer 2 according to the first embodiment. For convenience of explanation, the following description will be appropriately described using an α-axis intersecting the X-axis and the Y-axis in the X-Y plane and a β-axis intersecting the X-axis and the Y-axis in the X-Y plane. The α-axis and the β-axis are orthogonal to each other. The α-axis is tilted 45° to each of the X-axis and the Y-axis. The β-axis is tilted 45° to each of the X-axis and the Y-axis. In addition, one direction along the α-axis is defined as an α1 direction, and a direction opposite to the α1 direction is defined as an α2 direction. One direction along the β-axis is defined as a β1 direction, and a direction opposite to the β1 direction is defined as a β2 direction.

As illustrated in FIG. 5, the light-emitting element layer 2 includes one light-emitting element 20R, one light-emitting element 20G, and two light-emitting elements 20B for each pixel P. In this embodiment, the light-emitting element 20R corresponds to a “first light-emitting element”, and the light-emitting element 20G corresponds to a “second light-emitting element”. In addition, one of the two light-emitting elements 20B provided in each pixel P corresponds to a “third light-emitting element”, and another corresponds to a “fourth light-emitting element”.

The light-emitting element 20R has the light-emitting region AR that emits light in a wavelength region including the red wavelength region. The wavelengths in the red wavelength region are greater than 580 nm and 700 nm or less. The light-emitting element 20G has the light-emitting region AG that emits light in a wavelength region including the green wavelength region. The wavelengths of the green wavelength region are 500 nm or greater and 580 nm or less. The light-emitting element 20B has the light-emitting region AB that emits light in a wavelength region including the blue wavelength region. The wavelengths of the blue wavelength region are specifically 400 nm or greater and less than 500 nm.

In this embodiment, the light-emitting region AR corresponds to a “first light-emitting region”, and the light-emitting region AG corresponds to a “second light-emitting region”. The light-emitting region AB of the light-emitting element 20B corresponding to the “third light-emitting element” corresponds to a “third light-emitting region”, and the light-emitting region AB of the light-emitting element 20B corresponding to the “fourth light-emitting element” corresponds to a “fourth light-emitting region”.

As described above, the array of sub-pixels P0 is the Bayer array. Consequently, the array of the light-emitting regions A is the Bayer array. Thus, one light-emitting region AR, one light-emitting region AG, and two light-emitting regions AB constitute one set, and the two light-emitting regions AB are arranged obliquely for the array direction of the pixels P. In the Bayer array, the light-emitting elements 20 are arranged in two rows and two columns in one pixel P.

Specifically, in each pixel P, the plurality of light-emitting regions AB are aligned in the α1 direction. One of the two light-emitting regions AB is arranged in the X1 direction to the light-emitting region AR, and the other light-emitting region AB is arranged in the Y2 direction to the light-emitting region AR. In each pixel P, the light-emitting region AG is arranged in the β2 direction to the light-emitting region AR. Further, for example, when focusing on the pixel P located at the center in FIG. 5, the light-emitting region AR in the pixel P is surrounded by four light-emitting regions AB and four light-emitting regions AG. Similarly, the light-emitting region AG in the pixel P is surrounded by four light-emitting regions AR and four light-emitting regions AB.

Note that in the illustrated example, the shape of the light-emitting region A in plan view is substantially quadrangular, but the shape is not limited thereto, and may be, for example, hexagonal. The shapes of the light-emitting regions AR, AG, and AB in plan view are the same as each other, but may be different from each other. The areas of the light-emitting regions AR, AG, and AB in plan view are the same as each other, but may be different from each other.

FIG. 6 is a schematic plan view illustrating a part of color filter 5 according to the first embodiment. As illustrated in FIG. 6, the color filter 5 includes two types of filters. Specifically, the color filter 5 includes a plurality of magenta filters 50M and a plurality of cyan filters 50C. The plurality of magenta filters 50M and the plurality of cyan filters 50C are located on the same plane as each other. The magenta filter 50M is a magenta colored layer. The cyan filter 50C is a cyan colored layer. In this embodiment, the magenta filter 50M corresponds to a “first filter” and the cyan filter 50C corresponds to a “second filter”.

The plurality of magenta filters 50M are arranged in a check pattern in plan view. The plurality of cyan filters 50C are arranged in a check pattern in plan view. The plurality of magenta filters 50M and the plurality of cyan filters 50C are alternately arranged in a matrix in the α1 direction and the β2 direction. The boundary between the magenta filter 50M and the cyan filter 50C adjacent to each other extends in the α1 direction or the β2 direction. From another point of view, each side of the outer shape of each filter extends in the α1 direction or the β2 direction.

Each shape of the magenta filter 50M and the cyan filter 50C illustrated in FIG. 6 in plan view corresponds to the shape of the light-emitting region A illustrated in FIG. 5 in plan view. In the illustrated example, each shape of the plurality of magenta filters 50M and the plurality of cyan filters 50C is substantially quadrangular in plan view. Note that each shape of the magenta filter 50M and the cyan filter 50C in plan view may be, for example, hexagonal. In addition, the shapes of the magenta filter 50M and the cyan filter 50C in plan view are the same as each other, but may be different from each other.

In addition, each area of the magenta filter 50M and the cyan filter 50C illustrated in FIG. 6 in plan view is larger than the area of the light-emitting region A illustrated in FIG. 5 in plan view. Note that the areas of the magenta filter 50M and the cyan filter 50C in plan view are the same as each other, but may be different from each other.

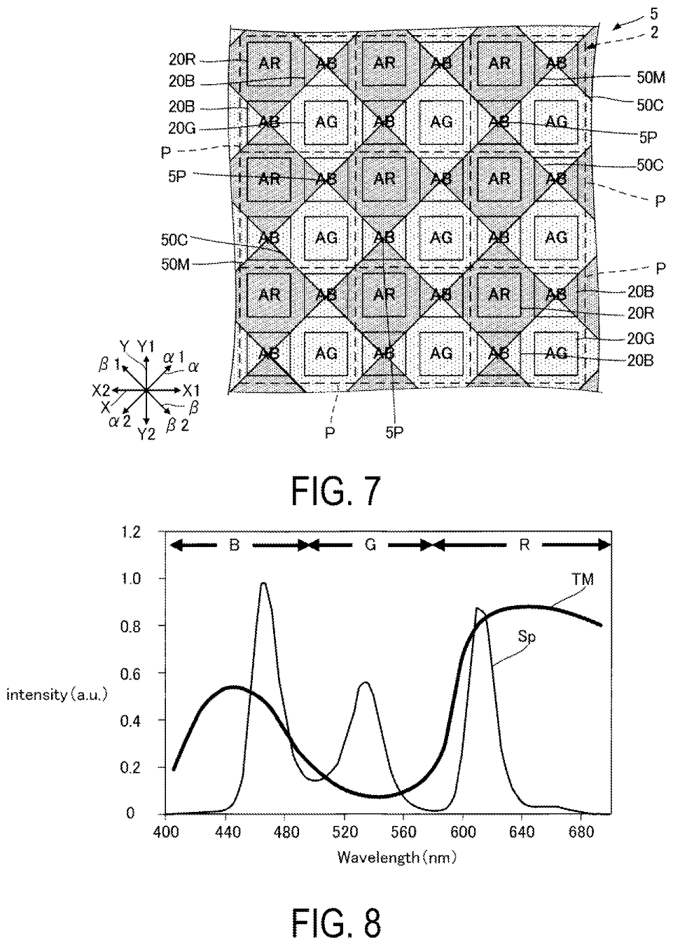

FIG. 7 is a schematic plan view illustrating an arrangement of the light-emitting element layer 2 and the color filter 5 according to the first embodiment. As illustrated in FIG. 7, the color filter 5 overlaps the light-emitting element layer 2 in plan view. The array direction of the magenta filter 50M and the cyan filter 50C intersect the array direction of the plurality of light-emitting regions A in plan view. As described above, the magenta filter 50M and the cyan filter 50C are alternately arranged in a matrix in the α1 direction and the β2 direction. The plurality of light-emitting regions A are arranged in a matrix in the X1 direction and the Y2 direction.

The plurality of the magenta filters 50M are arranged one-to-one for the plurality of light-emitting regions AR. Each magenta filter 50M is arranged in the X-Y plane in a state of being rotated by 45° from the corresponding light-emitting region AR. From another point of view, each magenta filter 50M has a rectangular shape with an outer side arranged obliquely to the X1 direction or the Y2 direction. Each light-emitting region AR overlaps the corresponding magenta filter 50M in plan view.

Similarly, the plurality of cyan filters 50C are arranged one-to-one for the plurality of light-emitting regions AG. Each cyan filter 50C is arranged in the X-Y plane in a state of being rotated by 45° from the corresponding light-emitting region AG. From another point of view, each cyan filter 50C has a rectangular shape with an outer side arranged obliquely to the X1 direction or the Y2 direction. Each light-emitting region AG overlaps the corresponding cyan filter 50C in plan view.

In addition, the magenta filter 50M projects from the light-emitting region AR toward each of the four adjacent light-emitting regions AB in plan view. Consequently, the magenta filter 50M overlaps one light-emitting region AR and each of parts of the four light-emitting regions AB in plan view. Note that the magenta filter 50M does not overlap the light-emitting region AG in plan view. Similarly, the cyan filter 50C projects from the light-emitting region AG toward each of the four adjacent light-emitting regions AB in plan view. Consequently, the cyan filter 50C overlaps one light-emitting region AG and each of parts of the four light-emitting regions AB in plan view. Note that the cyan filter 50C does not overlap the light-emitting region AR in plan view.

Thus, in plan view, the light-emitting region AB has portions overlapping the magenta filters 50M and portions overlapping the cyan filters 50C. In this embodiment, each of the parts of the two magenta filters 50M and each of the parts of the two cyan filters 50C are arranged in a well-balanced manner at the light-emitting region AB. In addition, a contact point 5P where the two magenta filters 50M and the two cyan filters 50C come into contact with each other is located at the light-emitting region AB.

FIG. 8 is a diagram for explaining the characteristics of the magenta filter 50M. In FIG. 8, an emission spectrum Sp of the light-emitting element layer 2 and a transmission spectrum. TM of the magenta filter 50M are illustrated. The emission spectrum Sp is the sum of the spectra of the three color light-emitting elements 20.

As illustrated in FIG. 8, the magenta filter 50M transmits light in the red wavelength region and light in the blue wavelength region, and absorbs light in the green wavelength region. That is, the magenta filter 50M has a lower transmittance of light in the green wavelength region than the transmittance of light in the red wavelength region and the transmittance of light in the blue wavelength region. The transmittance of light in the green wavelength region passed through the magenta filter 50M is preferably 50% or less, and more preferably 20% or less, to the maximum transmittance of visible light passed through the magenta filter 50M.

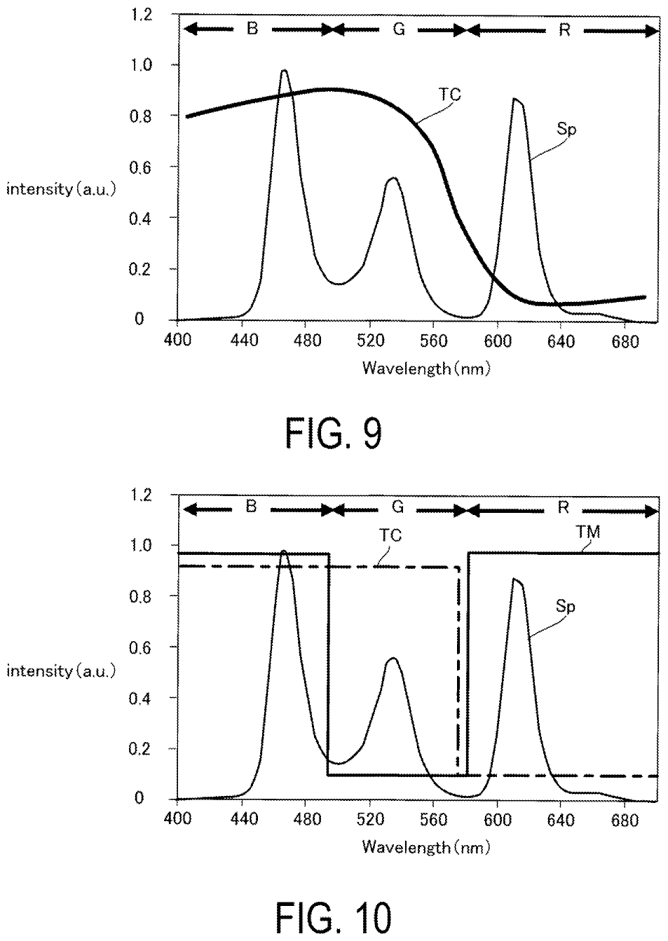

FIG. 9 is a diagram for explaining the characteristics of the cyan filter 50C. In FIG. 9, the emission spectrum Sp of the light-emitting element layer 2 illustrated in FIG. 3 and a transmission spectrum TC of the cyan filter 50C are illustrated.

As illustrated in FIG. 9, the cyan filter 50C transmits light in the green wavelength region and light in the blue wavelength region, and absorbs light in the red wavelength region. That is, the cyan filter 50C has a lower transmittance of light in the red wavelength region than the transmittance of light in the green wavelength region and the transmittance of light in the blue wavelength region. The transmittance of light in the red wavelength region passed through the cyan filter 50C is preferably 50% or less, and more preferably 20% or less, to the maximum transmittance of visible light passed through the cyan filter 50C.

FIG. 10 is a diagram for explaining the characteristics of the color filter 5 according to the first embodiment. In FIG. 10, for convenience of explanation, the transmission spectrum TM of the magenta filter 50M and the transmission spectrum TC of the cyan filter 50C are illustrated in a simplified manner.

As illustrated in FIG. 10, by using the two types of filters, the magenta filter 50M and the cyan filter 50C, the color filter 5 can transmit light in the wavelength regions of red, green, and blue.

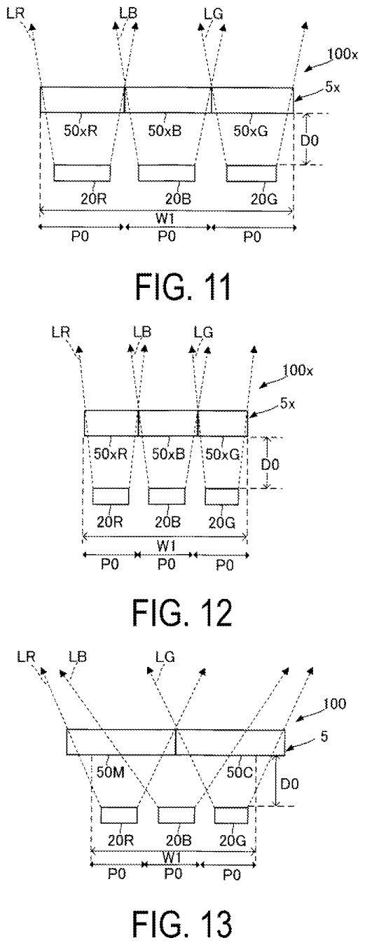

FIG. 11 is a schematic diagram illustrating an electro-optical device 100x having a known color filter 5x. An “x” is added to reference signs of elements related to the known electro-optical device 100x.

The color filter 5x included in the electro-optical device 100x includes a filter corresponding to the light-emitting element 20 for each sub-pixel P0. The color filter 5x includes a filter 50xR that selectively transmits light in the red wavelength region, a filter 50xG that selectively transmits light in the green wavelength region, and a filter 50xB that selectively transmits light in the blue wavelength region. Although the plan view is omitted, the filter 50xR overlaps the light-emitting element 20R in plan view, the filter 50xG overlaps the light-emitting element 20G in plan view, and the filter 50xB overlaps the light-emitting element 20B in plan view.

In the electro-optical device 100x, light LB in the blue wavelength region emitted from the light-emitting element 20B passes through the filter 50xB. Note that the light LB in the blue wavelength region is absorbed by the filter 50xG and the filter 50xR adjacent to the filter 50xB. Similarly, light LR in the red wavelength region emitted from the light-emitting element 20R passes through the filter 50xR. Note that, although not illustrated in detail, the light LR in the red wavelength region is absorbed by the filter 50xG and the filter 50xB adjacent to the filter 50xR. Further, light LG in the green wavelength region emitted from the light-emitting element 20G passes through the filter 50xG. Note that, although not illustrated in detail, the light LG in the green wavelength region is absorbed by the filter 50xR and the filter 50xB adjacent to the filter 50xG.

FIG. 12 is a schematic diagram illustrating an example when the electro-optical device 100x of FIG. 11 is miniaturized. As illustrated in FIG. 12, when a width W1 of the pixel P is reduced in order to reduce the size of the electro-optical device 100x of FIG. 11, the width of each sub-pixel P0 is also reduced. Note that a distance DO between the color filter 5x and each light-emitting element 20x is not changed. As the width of the sub-pixel P0 becomes smaller, the width of each filter 50x also becomes smaller. As a result, the spreading angle of the light passed through the color filter 5x becomes smaller. Specifically, the spreading angle of the light LG passed through the filter 50xG, the spreading angle of the light LR passed through the filter 50xR, and the spreading angle of the light LB passed through the filter 50xB are each reduced.

FIG. 13 is a schematic diagram illustrating the electro-optical device 100 according to the first embodiment. As illustrated in FIG. 13, the color filter 5 according to this embodiment includes the two types of filters, and filters are not arranged separately for each sub-pixel P0. Thus, in the electro-optical device 100, the number of types of filters included in the color filter 5 is less than the number of types of the light-emitting elements 20. Then, in the electro-optical device 100, the magenta filter 50M overlaps the light-emitting element 20R and the light-emitting element 20B in plan view, and the cyan filter 50C overlaps the light-emitting element 20G and the light-emitting element 20B in plan view.

As described above, the light LB in the blue wavelength region emitted from the light-emitting element 20B passes through the magenta filter 50M and the cyan filter 50C. Thus, the light LB passes through the color filter 5 without being absorbed by the color filter 5.

Further, the light LR in the red wavelength region emitted from the light-emitting element 20R passes through the magenta filter 50M. The light LG in the green wavelength region emitted from the light-emitting element 20G passes through the cyan filter 50C. As described above, since the number of types of filters included in the color filter 5 is less than the number of types of the light-emitting elements 20, the width of each filter can be made larger than that of the known filter. Consequently, the width of the magenta filter 50M can be made larger than the width of the known filter 50xR. Thus, the spreading angle of the light LR passed through the magenta filter 50M can be larger than the spreading angle of the light LR passed through the known filter 50xR. Similarly, the width of the cyan filter 50C can be made larger than the width of the known filter 50xG. Consequently, the spreading angle of the light LG passed through the cyan filter 50C can be made larger than the spreading angle of the light LG passed through the known filter 50xG.

As described above, the electro-optical device 100 includes the light-emitting element 20R, the light-emitting element 20G, the light-emitting element 20B, the magenta filter 50M, and the cyan filter 50C. Then, the light-emitting region AR overlaps the magenta filter 50M in plan view. The light-emitting region AG overlaps the cyan filter 50C in plan view. In plan view, the light-emitting region AB has the portions overlapping the magenta filters 50M and the portions overlapping the cyan filters 50C.

As described above, by providing the two types of filters for the three types of light-emitting elements 20, the flat area of each filter can be increased as compared with the case in which the three types of filters corresponding to each of the three types of light-emitting elements 20 are provided. Consequently, it is possible to suppress the absorbing of light from each light-emitting element 20 by the filter.

Specifically, the magenta filter 50M and the cyan filter 50C are arranged as illustrated in FIG. 7 for the three types of light-emitting elements 20. As illustrated in FIG. 7, the magenta filter 50M located at the light-emitting region AR projects from the light-emitting region AR to the four adjacent light-emitting regions AB in plan view. Consequently, light in the red wavelength region from the light-emitting region AR spreads from the light-emitting region AR onto the four adjacent light-emitting regions AB and passes through the magenta filter 50M. Similarly, the cyan filter 50C located at the light-emitting region AG projects from the light-emitting region AG to the four adjacent light-emitting regions AB in plan view. Consequently, light in the green wavelength region from the light-emitting region AG spreads from the light-emitting region AG onto the four adjacent light-emitting regions AB and passes through the cyan filter 50C.

Further, light in the blue wavelength region from the light-emitting region AB passes through the magenta filter 50M and the cyan filter 50C. Consequently, light in the blue wavelength region from the light-emitting region AB passes through the color filter 5 without being absorbed by the filter.

Therefore, according to the electro-optical device 100, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced. Further, since the absorbing of the light from each light-emitting element 20 by the filter is suppressed, the opening ratio for each sub-pixel P0 can be improved.

In addition, in this embodiment, the light-emitting region AB that emits light in the blue wavelength region, which is the wavelength region having the shortest wavelengths, has the portions overlapping the magenta filters 50M and the portions overlapping the cyan filters 50C in plan view. For example, when the spreading angle of the light from the light-emitting element 20B or the luminous efficiency of the light-emitting element 20B is inferior to that of the other light-emitting elements 20 due to the configuration of the light-emitting element 20B, the difference in light intensity from the other wavelength regions can be suppressed by using two types of filters that transmit light in the blue wavelength region. Further, in the light-emitting element layer 2, the total area of the light-emitting region AB is the largest in each pixel P. Consequently, for example, when the lifespan of the light-emitting element 20B is inferior to that of the other light-emitting elements 20, the difference in the light intensity from the other wavelength regions can be suppressed for a long period of time.

Further, as described above, in this embodiment, the light-emitting element 20R having the light-emitting region AR, the light-emitting element 20G having the light-emitting region AG, and the two light-emitting elements 20B having the light-emitting regions AB are provided for each pixel P. The array of the light-emitting region AR, the light-emitting region AG, and the two light-emitting regions AB is the Bayer array. Further, as illustrated in FIG. 7, in one pixel P, the magenta filter 50M and the cyan filter 50C are aligned in the β2 direction intersecting the α1 direction in which the two light-emitting regions AB are arranged. When the array of the light-emitting regions A is the Bayer array, the magenta filter 50M and the cyan filter 50C can be efficiently arranged by arranging the magenta filter 50M and the cyan filter 50C as described above.

Further, as described above, the plurality of pixels P are arranged in a matrix in the X1 direction and the Y1 direction in plan view. The plurality of magenta filters 50M and the plurality of cyan filters 50C are alternately arranged in a matrix in the α1 direction and the β1 direction in plan view. When the array of the light-emitting regions A is the Bayer array, by intersecting the array direction of the plurality of pixels P with the array direction of the plurality of magenta filters 50M and the plurality of cyan filters 50C, the magenta filters 50M and the cyan filters 50C can be efficiently arranged. Consequently, the total number of the magenta filters 50M and the cyan filters 50C can be reduced as compared with a case in which the array direction of the plurality of pixels P and the array direction of the plurality of magenta filters 50M and the plurality of cyan filters 50C are the same. Thus, since each flat area of the magenta filter 50M and the cyan filter 50C can be increased, the spreading angle of the light can be increased.

Note that the row direction and the column direction of the plurality of pixels P may not be orthogonal to each other and may intersect each other at less than 90°. Similarly, the row direction and the column direction of the plurality of filters included in the color filter 5 may not be orthogonal to each other and may intersect each other at less than 90°.

In addition, since the array of the light-emitting elements 20 is the Bayer array, the three types of light-emitting elements 20 are arranged in two rows and two columns in each pixel P. Consequently, the visual field angle characteristics can be improved as compared with, for example, a stripe array in which three types of light-emitting elements 20 are arranged in three rows and one column, and a rectangle array described later. In particular, the Bayer array can reduce the difference in visual field angle characteristics in the X1, X2, Y1, and Y2 directions by the combination of the adjacent sub-pixels P0. Thus, by using the light-emitting element layer 2 in which the light-emitting elements 20 are arranged in the Bayer array and the color filter 5, it is possible to suppress the lowering of the visual field angle characteristics in various directions.

Further, as described above, the light-emitting element 20R, the light-emitting element 20G, and the light-emitting element 20B have the different optical resonance structures 29 from each other. The light-emitting element 20R has the light resonance structure 29R that enhances light in the red wavelength region, the light-emitting element 20G has the optical resonance structure 29G that enhances light in the green wavelength region, and the light-emitting element 20B has the optical resonance structure 29B that enhances light in the blue wavelength region. By providing the optical resonance structure 29, it is possible to increase the intensity of light and narrow the spectrum of light. Using the color filter 5 for the light-emitting element 20 provided with the optical resonance structure 29, it is possible to improve the color purity and the visual field angle characteristics.

### 1B. Second Embodiment

A second embodiment will be described. Note that, for the elements having the same functions as those of the first embodiment in each of the following examples, the reference signs used in the description of the first embodiment will be used and detailed description of each will be appropriately omitted.

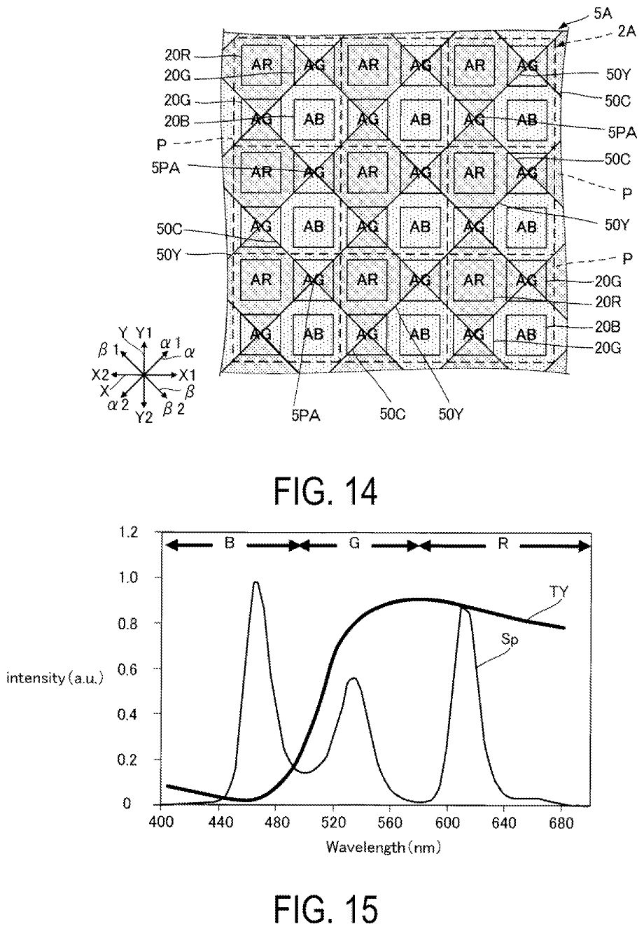

FIG. 14 is a schematic plan view illustrating an arrangement of a light-emitting element layer 2A and a color filter 5A according to the second embodiment. Hereinafter, regarding the light-emitting element layer 2A and the color filter 5A, items different from the light-emitting element layer 2 and the color filter 5 according to the first embodiment will be described, and description of the same items will be omitted.

The light-emitting element layer 2A illustrated in FIG. 14 has one light-emitting element 20R, one light-emitting element 20B, and two light-emitting elements 20G for each pixel P. Note that, although not illustrated, in this embodiment, each pixel P has one sub-pixel PR, one sub-pixel PB, and two sub-pixels PG.

In this embodiment, the light-emitting element 20R corresponds to the “first light-emitting element”, and the light-emitting element 20B corresponds to the “second light-emitting element”. One of the two light-emitting elements 20G provided in each pixel P corresponds to the “third light-emitting element” and another corresponds to the “fourth light-emitting element”. Further, the light-emitting region AR corresponds to the “first light-emitting region”, and the light-emitting region AB corresponds to the “second light-emitting region”. The light-emitting region AG of the light-emitting element 20G corresponding to the “third light-emitting element” corresponds to the “third light-emitting region”, and the light-emitting region AG of the light-emitting element 20G corresponding to the “fourth light-emitting element” corresponds to the “fourth light-emitting region”. In addition, the red wavelength region corresponds to the “first wavelength region”, the blue wavelength region corresponds to the “second wavelength region”, and the green wavelength region corresponds to the “third wavelength region”.

Further, since the array of the light-emitting regions A is the Bayer array, one light-emitting region AR, one light-emitting region AB, and two light-emitting regions AG constitute one set, and the two light-emitting regions AG are arranged obliquely for the array direction of the pixels P. Specifically, in each pixel P, the plurality of light-emitting regions AG are aligned in the α1 direction. One of the two light-emitting regions AG is arranged in the X1 direction to the light-emitting region AR, and the other light-emitting region AG is arranged in the Y2 direction to the light-emitting region AR. In each pixel P, the light-emitting region AB is arranged in the β2 direction to the light-emitting region AR.

The color filter 5A includes a plurality of yellow filters 50Y and the plurality of cyan filters 50C. The plurality of yellow filters 50Y and the plurality of cyan filters 50C are located on the same plane as each other. In this embodiment, the yellow filter 50Y corresponds to the “first filter”, and the cyan filter 50C corresponds to the “second filter”. The yellow filter 50Y is a yellow colored layer. The plurality of yellow filters 50Y are arranged in a check pattern in plan view. Further, the plurality of yellow filters 50Y and the plurality of cyan filters 50C are alternately arranged in a matrix in the α1 direction and the β2 direction. The boundary between the yellow filter 50Y and the cyan filter 50C adjacent to each other extends in the α1 direction or the β2 direction.

The shape of the yellow filter 50Y in plan view corresponds to the shape of the light-emitting region AR in plan view, and is quadrangular. Each light-emitting region AR overlaps the corresponding yellow filter 50Y in plan view. In the X-Y plane, the yellow filter 50Y is arranged in a state of being rotated 45° from the light-emitting region AR. From another point of view, each yellow filter 50Y has a rectangular shape with an outer side arranged obliquely to the X1 direction or the Y2 direction. In addition, the shape of the cyan filter 50C in plan view corresponds to the shape of the light-emitting region AB in plan view, and is quadrangular. Each light-emitting region AB overlaps the corresponding cyan filter 50C in plan view. In the X-Y plane, the cyan filter 50C is arranged in a state of being rotated 45° from the light-emitting region AB. From another point of view, each cyan filter 50C has a rectangular shape with an outer side arranged obliquely to the X1 direction or the Y2 direction.

In addition, the yellow filter 50Y projects from the light-emitting region AR toward each of the four adjacent light-emitting regions AG in plan view. Consequently, the yellow filter 50Y overlaps one light-emitting region AR and each of parts of the four light-emitting regions AG in plan view. Note that the yellow filter 50Y does not overlap the light-emitting region AB in plan view. Similarly, the cyan filter 50C projects from the light-emitting region AB toward each of the four adjacent light-emitting regions AG in plan view. Consequently, the cyan filter 50C overlaps one light-emitting region AB and each of parts of the four light-emitting regions AG in plan view. Note that the cyan filter 50C does not overlap the light-emitting region AR in plan view.

Thus, in plan view, the light-emitting region AG has portions overlapping the yellow filters 50Y and portions overlapping the cyan filters 50C. In this embodiment, each of the parts of the two yellow filters 50Y and each of the parts of the two cyan filters 50C are arranged in a well-balanced manner at the light-emitting region AG. In addition, a contact point 5PA where the two yellow filters 50Y and the two cyan filters 50C come into contact with each other is located at the light-emitting region AG.

FIG. 15 is a diagram for explaining the characteristics of the yellow filter 50Y. A transmission spectrum TY of the yellow filter 50Y is illustrated in FIG. 15. As illustrated in FIG. 15, the yellow filter 50Y transmits light in the red wavelength region and light in the green wavelength region, and absorbs light in the blue wavelength region. That is, the yellow filter 50Y has a lower transmittance of light in the blue wavelength region than the transmittance of light in the red wavelength region and the transmittance of light in the green wavelength region. The transmittance of light in the blue wavelength region passed through the yellow filter 50Y is preferably 50% or less, and more preferably 20% or less, to the maximum transmittance of visible light passed through the yellow filter 50Y.

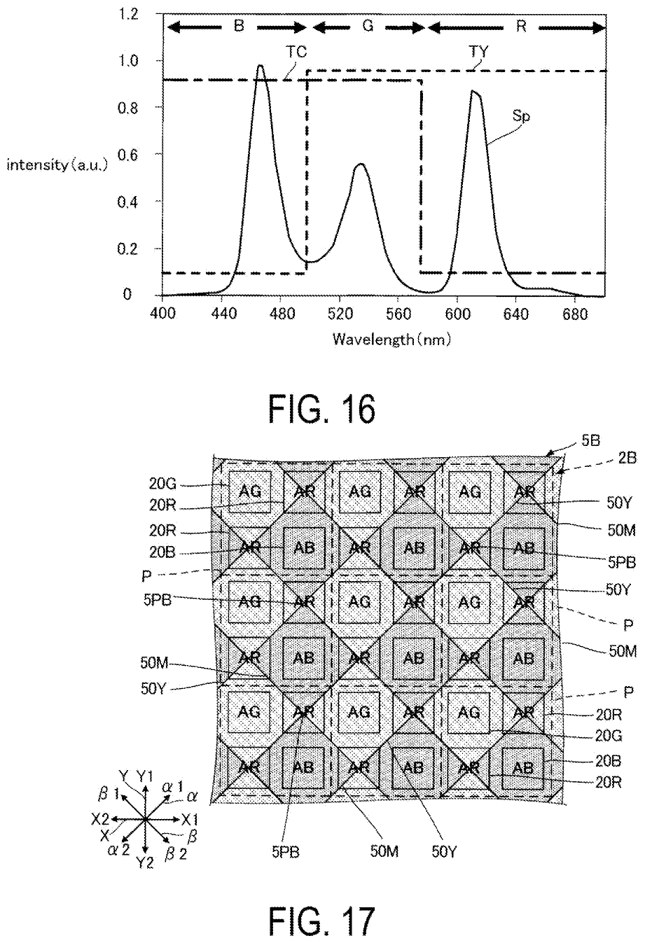

FIG. 16 is a diagram for explaining the characteristics of the color filter 5A according to the second embodiment. In FIG. 16, for convenience of explanation, the transmission spectrum TY of the yellow filter 50Y and the transmission spectrum TC of the cyan filter 50C are illustrated in a simplified manner. As illustrated in FIG. 16, by using the two types of filters, the yellow filter 50Y and the cyan filter 50C, the color filter 5A can transmit light in the wavelength regions of red, green, and blue.

As described above, in this embodiment, the yellow filter 50Y and the cyan filter 50C are arranged as illustrated in FIG. 14 for the light-emitting element 20R, the light-emitting element 20G, and the light-emitting element 20B. In this embodiment as well, as in the first embodiment, by providing the two types of filters for the three types of light-emitting elements 20, the flat area of each filter can be increased. Consequently, it is possible to suppress the absorbing of light from each light-emitting element 20 by the filter.

Specifically, as illustrated in FIG. 14, the yellow filter 50Y located at the light-emitting region AR projects from the light-emitting region AR to the four adjacent light-emitting regions AG in plan view. Consequently, light in the red wavelength region from the light-emitting region AR spreads from the light-emitting region AR onto the four adjacent light-emitting regions AG and passes through the yellow filter 50Y. Similarly, the cyan filter 50C located at the light-emitting region AB projects from the light-emitting region AB to the four adjacent light-emitting regions AG in plan view. Consequently, light in the blue wavelength region from the light-emitting region AB spreads from the light-emitting region AB onto the four adjacent light-emitting regions AG and passes through the cyan filter 50C.

Further, light in the green wavelength region from the light-emitting region AG passes through the yellow filter 50Y and the cyan filter 50C. Consequently, light in the green wavelength region from the light-emitting region AG passes through the color filter 5A without being absorbed by the filter.

Therefore, in this embodiment as well, similar to the first embodiment, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced. In addition, the opening ratio for each sub-pixel P0 can be improved.

Further, the color filter 5A includes two types of filters that transmit light in the green wavelength region from the light-emitting region AG. Further, in the light-emitting element layer 2A, the total area of the light-emitting region AG is the largest in each pixel P. For example, when it is desired to make light in the green wavelength region higher in intensity than light in the other wavelength regions in accordance with the desired color balance, it is effective to use the light-emitting element layer 2A and the color filter 5A.

Further, the array of the light-emitting regions A is the Bayer array. Consequently, in one pixel P, the yellow filter 50Y and the cyan filter 50C are aligned in the β1 direction intersecting the α1 direction in which the two light-emitting regions AG are aligned. Therefore, the yellow filter 50Y and the cyan filter 50C can be efficiently arranged. In addition, the array direction of the plurality of pixels P, and the array direction of the plurality of yellow filters 50Y and the plurality of cyan filters 50C intersect each other. Therefore, the yellow filter 50Y and the cyan filter 50C can be efficiently arranged.

The light-emitting element layer 2A and the color filter 5A according to the second embodiment described above can also improve the visual field angle characteristics, as in the first embodiment.

### 1C. Third Embodiment

A third embodiment will be described. Note that, for the elements having the same functions as those of the first embodiment in each of the following examples, the reference signs used in the description of the first embodiment will be used and detailed description of each will be appropriately omitted.

FIG. 17 is a schematic plan view illustrating an arrangement of a light-emitting element layer 2B and a color filter 5B according to the third embodiment. Hereinafter, regarding the light-emitting element layer 2B and the color filter 5B, items different from the light-emitting element layer 2 and the color filter 5 according to the first embodiment will be described, and description of the same items will be omitted.

The light-emitting element layer 2B illustrated in FIG. 17 has one light-emitting element 20G, one light-emitting element 20B, and two light-emitting elements 20R for each pixel P. Note that, although not illustrated, in this embodiment, each pixel P has one sub-pixel PG, one sub-pixel PB, and two sub-pixels PR.

In this embodiment, the light-emitting element 20G corresponds to the “first light-emitting element”, and the light-emitting element 20B corresponds to the “second light-emitting element”. One of the two light-emitting elements 20R provided in each pixel P corresponds to the “third light-emitting element” and another corresponds to the “fourth light-emitting element”. Further, the light-emitting region AG corresponds to the “first light-emitting region”, and the light-emitting region AB corresponds to the “second light-emitting region”. The light-emitting region AR of the light-emitting element 20R corresponding to the “third light-emitting element” corresponds to the “third light-emitting region”, and the light-emitting region AR of the light-emitting element 20R corresponding to the “fourth light-emitting element” corresponds to the “fourth light-emitting region”. In addition, the green wavelength region corresponds to the “first wavelength region”, the blue wavelength region corresponds to the “second wavelength region”, and the red wavelength region corresponds to the “third wavelength region”.

Further, since the array of the light-emitting regions A is the Bayer array, one light-emitting region AG, one light-emitting region AB, and two light-emitting regions AR constitute one set, and the two light-emitting regions AR are arranged obliquely for the array direction of the pixels P. Specifically, in each pixel P, the plurality of light-emitting regions AR are aligned in the α1 direction. One of the two light-emitting regions AR is arranged in the X1 direction to the light-emitting region AG, and the other light-emitting region AR is arranged in the Y2 direction to the light-emitting region AG. In each pixel P, the light-emitting region AB is arranged in the β2 direction to the light-emitting region AG.

The color filter 5B includes the plurality of yellow filters 50Y and the plurality of magenta filters 50M. The plurality of yellow filters 50Y and the plurality of magenta filters 50M are located on the same plane as each other. In this embodiment, the yellow filter 50Y corresponds to the “first filter”, and the magenta filter 50M corresponds to the “second filter”. The yellow filter 50Y is a yellow colored layer. The plurality of yellow filters 50Y are arranged in a check pattern in plan view. In addition, the plurality of yellow filters 50Y and the plurality of magenta filters 50M are alternately arranged in a matrix in the α1 direction and the β2 direction. The boundary between the yellow filter 50Y and the magenta filter 50M adjacent to each other extends in the α1 direction or the β2 direction.

The shape of the yellow filter 50Y in plan view corresponds to the shape of the light-emitting region AG in plan view, and is quadrangular. Each light-emitting region AG overlaps the corresponding yellow filter 50Y in plan view. In the X-Y plane, the yellow filter 50Y is arranged in a state of being rotated 45° from the light-emitting region AG. From another point of view, each yellow filter 50Y has a rectangular shape with an outer side arranged obliquely to the X1 direction or the Y2 direction. In addition, the shape of the magenta filter 50M in plan view corresponds to the shape of the light-emitting region AB in plan view, and is quadrangular. Each light-emitting region AB overlaps the corresponding magenta filter 50M in plan view. In the X-Y plane, the magenta filter 50M is arranged in a state of being rotated 45° from the light-emitting region AB. From another point of view, each magenta filter 50M has a rectangular shape with an outer side arranged obliquely to the X1 direction or the Y2 direction.

In addition, the yellow filter 50Y projects from the light-emitting region AG toward each of the four adjacent light-emitting regions AR in plan view. Consequently, the yellow filter 50Y overlaps one light-emitting region AG and each of parts of the four light-emitting regions AR in plan view. Note that the yellow filter 50Y does not overlap the light-emitting region AB in plan view. Similarly, the magenta filter 50M projects from the light-emitting region AB toward each of the four adjacent light-emitting regions AR in plan view. Consequently, the magenta filter 50M overlaps one light-emitting region AB and each of parts of the four light-emitting regions AR in plan view. Note that the magenta filter 50M does not overlap the light-emitting region AG in plan view.

Thus, in plan view, the light-emitting region AR has portions overlapping the yellow filters 50Y and portions overlapping the magenta filters 50M. In this embodiment, each of the parts of the two yellow filters 50Y and each of the parts of the two magenta filters 50M are arranged in a well-balanced manner at the light-emitting region AR. In addition, a contact point 5PB where the two yellow filters 50Y and the two magenta filters 50M come into contact with each other is located at the light-emitting region AR.

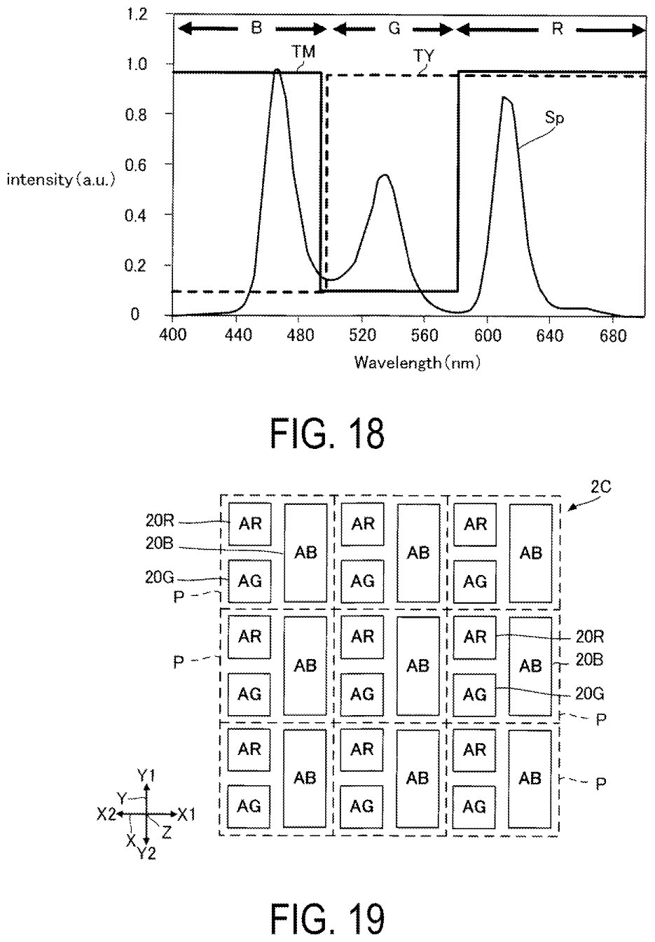

FIG. 18 is a diagram for explaining the characteristics of the color filter 5B according to the third embodiment. In FIG. 18, for convenience of explanation, the transmission spectrum TY of the yellow filter 50Y and the transmission spectrum TM of the magenta filter 50M are illustrated in a simplified manner. Note that the characteristics of the yellow filter 50Y are illustrated in FIG. 15.

As illustrated in FIG. 18, by using the two types of filters, the yellow filter 50Y and the magenta filter 50M, the color filter 5B can transmit light in the wavelength regions of red, green, and blue.

As described above, in this embodiment, the yellow filter 50Y and the magenta filter 50M are arranged as illustrated in FIG. 17 for the light-emitting element 20R, the light-emitting element 20G, and the light-emitting element 20B. In this embodiment as well, as in the first embodiment, by providing the two types of filters for the three types of light-emitting elements 20, the flat area of each filter can be increased. Consequently, it is possible to suppress the absorbing of light from each light-emitting element 20 by the filter.

Specifically, as illustrated in FIG. 17, the yellow filter 50Y located at the light-emitting region AG projects from the light-emitting region AG to the four adjacent light-emitting regions AR in plan view. Consequently, light in the green wavelength region from the light-emitting region AG spreads from the light-emitting region AG onto the four adjacent light-emitting regions AR and passes through the yellow filter 50Y. Similarly, the magenta filter 50M located at the light-emitting region AB projects from the light-emitting region AB to the four adjacent light-emitting regions AR in plan view. Consequently, light in the blue wavelength region from the light-emitting region AB spreads from the light-emitting region AB onto the four adjacent light-emitting regions AR and passes through the magenta filter 50M.

Further, light in the red wavelength region from the light-emitting region AR passes through the yellow filter 50Y and the magenta filter 50M. Consequently, light in the red wavelength region from the light-emitting region AR passes through the color filter 5B without being absorbed by the filter.

Therefore, in this embodiment as well, similar to the first embodiment, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced. In addition, the opening ratio for each sub-pixel P0 can be improved.

Further, the color filter 5B includes two types of filters that transmit light in the red wavelength region from the light-emitting region AR. Further, as described above, in the light-emitting element layer 2B, the total area of the light-emitting region AR is the largest in each pixel P. For example, when it is desired to make light in the red wavelength region higher in intensity than light in the other wavelength regions in accordance with the desired color balance, it is effective to use the light-emitting element layer 2B and the color filter 5B.

Further, the array of the light-emitting regions A is the Bayer array. Consequently, in one pixel P, the yellow filter 50Y and the magenta filter 50M are aligned in the β1 direction intersecting the α1 direction in which the two light-emitting regions AR are aligned. Therefore, the yellow filter 50Y and the magenta filter 50M can be efficiently arranged. In addition, the array direction of the plurality of pixels P, and the array direction of the plurality of yellow filters 50Y and the plurality of the magenta filters 50M intersect each other. Therefore, the yellow filter 50Y and the magenta filter 50M can be efficiently arranged.

The light-emitting element layer 2B and the color filter 5B according to the third embodiment described above can also improve the visual field angle characteristics, as in the first embodiment.

### 1D. Fourth Embodiment

A fourth embodiment will be described. Note that, for the elements having the same functions as those of the first embodiment in each of the following examples, the reference signs used in the description of the first embodiment will be used and detailed description of each will be appropriately omitted.

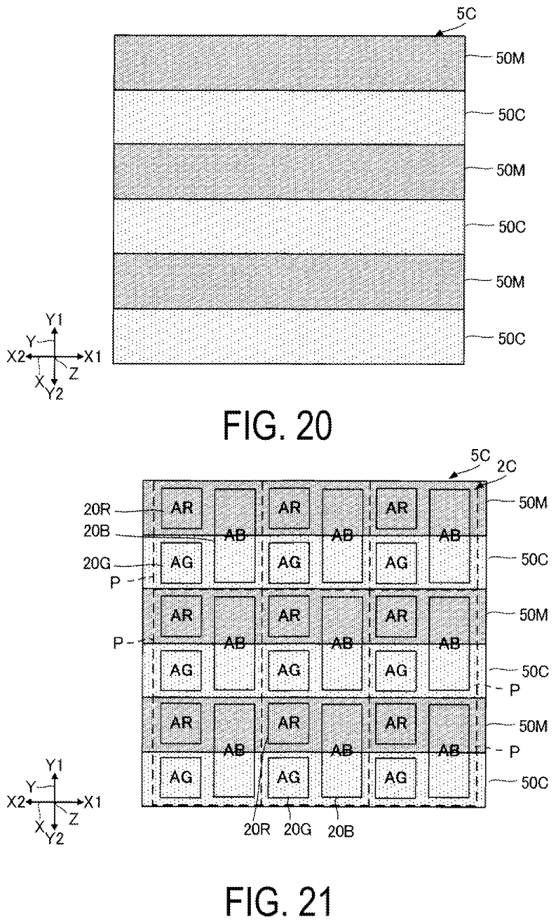

FIG. 19 is a schematic plan view illustrating a part of a light-emitting element layer 2C according to the fourth embodiment. FIG. 20 is a schematic plan view illustrating a part of a color filter 5C according to the fourth embodiment. In this embodiment, the light-emitting element layer 2C and the color filter 5C are differ from the light-emitting element layer 2 and the color filter 5 according to the first embodiment. Hereinafter, regarding the light-emitting element layer 2C and the color filter 5C, items different from the light-emitting element layer 2 and the color filter 5 according to the first embodiment will be described, and description of the same items will be omitted.

Further, in this embodiment, although not illustrated, the array of the sub-pixels P0 is a rectangle array. The rectangle array is an array in which one sub-pixel PR, one sub-pixel PG, and one sub-pixel PB constitute one pixel P, and is different from the stripe array. The direction in which the three sub-pixels P0 included in the rectangle array are aligned is not one direction.

As illustrated in FIG. 19, the light-emitting element layer 2C includes one light-emitting element 20R, one light-emitting element 20G, and one light-emitting element 20B for each pixel P. The array of the light-emitting regions A is the rectangle array. Thus, one light-emitting region AR, one light-emitting region AG, and one light-emitting region AB constitute one set. Further, the direction in which the light-emitting region AR and the light-emitting region AG are aligned is different from the direction in which the light-emitting region AR and the light-emitting region AB are aligned, and the direction in which the light-emitting region AG and the light-emitting region AB are aligned. The direction in which the light-emitting region AR and the light-emitting region AB are aligned is the same as the direction in which the light-emitting region AG and the light-emitting region AB are aligned, and in the illustrated example, the direction is the X1 direction. The direction in which the light-emitting region AR and the light-emitting region AG are aligned is the Y2 direction.

Further, in this embodiment, the area of the light-emitting region AB among the three light-emitting regions A is the largest. The light-emitting region AB is rectangular, and each of the light-emitting region AR and the light-emitting region AG is square. In the Y2 direction, the light-emitting region AB is wider than the light-emitting regions AR and AG. Note that the areas of the light-emitting regions AR and AG in plan view are equal to each other, but may be different. In addition, the plurality of light-emitting regions AR and the plurality of light-emitting regions AG are aligned in the Y2 direction. Similarly, the plurality of light-emitting regions AB are aligned in the Y2 direction. The rows in which the plurality of light-emitting regions AR and the plurality of light-emitting regions AG are aligned and the rows in which the plurality of light-emitting regions AB are aligned are alternately arranged in the X1 direction. In addition, it can be said that one light-emitting region AR, one light-emitting region AG, and one light-emitting region AB included in each pixel P according to this embodiment are within a range of the sub-pixels P0 arranged in two rows and two columns according to the first embodiment. In each pixel P, the area of the light-emitting region AB according to this embodiment in plan view is equal to or larger than the total area of the two light-emitting regions AB according to the first embodiment.

As illustrated in FIG. 20, the color filter 5C includes the plurality of magenta filters 50M and the plurality of cyan filters 50C. The plurality of magenta filters 50M and the plurality of cyan filters 50C are arranged in a stripe shape. In the color filter 5C, two types of long filters having different colors are arranged alternately. In the illustrated example, the magenta filter 50M and the cyan filter 50C each have a long shape extending in the X1 direction in plan view. The plurality of magenta filters 50M and the plurality of cyan filters 50C are arranged alternately in the Y2 direction.

FIG. 21 is a schematic plan view illustrating an arrangement of the light-emitting element layer 2C and the color filter 5C according to the fourth embodiment. As illustrated in FIG. 21, the light-emitting region AR overlaps the magenta filter 50M in plan view. The light-emitting region AG overlaps the cyan filter 50C in plan view. In plan view, the light-emitting region AB has a portion overlapping the magenta filter 50M and a portion overlapping the cyan filter 50C.

As described above, in this embodiment, the magenta filter 50M and the cyan filter 50C are arranged as illustrated in FIG. 21 for the light-emitting element 20R, the light-emitting element 20G, and the light-emitting element 20B. In this embodiment as well, as in the first embodiment, by providing the two types of filters for the three types of light-emitting elements 20, the flat area of each of the filters can be increased as compared with the case in which the three types of filters corresponding to each of the three types of light-emitting elements 20 are provided. Consequently, it is possible to suppress the absorbing of light from each light-emitting element 20 by the filter.

Specifically, as illustrated in FIG. 21, the shape of the magenta filter 50M in plan view is a long shape extending in the X1 direction. Consequently, light in the red wavelength region from the light-emitting region AR spreads in the X1 direction and the X2 direction and passes through the magenta filter 50M. Similarly, the shape of the cyan filter 50C in plan view is a long shape extending in the X1 direction. Consequently, light in the green wavelength region from the light-emitting region AG spreads in the X1 direction and the X2 direction and passes through the cyan filter 50C.

Further, light in the blue wavelength region from the light-emitting region AB passes through the magenta filter 50M and the cyan filter 50C. Consequently, light in the blue wavelength region from the light-emitting region AB passes through the color filter 5C without being absorbed by the filter.

Therefore, in this embodiment as well, similar to the first embodiment, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced. In addition, the opening ratio for each sub-pixel P0 can be improved.

In this embodiment, as described above, the array of the light-emitting regions AR, AG, and AB is the rectangle array. Then, the magenta filter 50M and the cyan filter 50C are aligned in the direction in which the light-emitting region AR and the light-emitting region AG are aligned. Since the magenta filter 50M and the cyan filter 50C are arranged in this way, the magenta filter 50M and the cyan filter 50C can be efficiently arranged. Consequently, the total number of the magenta filters 50M and the cyan filters 50C can be reduced, and thus each flat area of the magenta filters 50M and the cyan filters 50C can be increased. Thus, it is possible to increase the spreading angle when light in the red wavelength region from the light-emitting region AR and light in the green wavelength region from the light-emitting region AG pass through the color filter 5C. In addition, by arranging the two types of filters in the stripe shape, each filter and the light-emitting element layer 2C can be brought into close contact with each other in a wider area than when the filters are arranged for each of the three types of sub-pixels P0. Consequently, it is easy to design and manufacture.

By using the light-emitting element layer 2C and the color filter 5C according to this embodiment, the visual field angle characteristics in the X1 direction and the X2 direction can be particularly enhanced. Accordingly, it is effective to use the electro-optical device 100 according to this embodiment in an apparatus that particularly requires the visual field angle characteristics in the X1 direction and the X2 direction as compared with the electro-optic device 100 according to the first embodiment. It is desirable to select the optimum form of the electro-optical device 100 according to the purpose of use.

Further, as described above, in the Bayer array according to the first embodiment, four light-emitting elements 20 are provided in each pixel P. In contrast, in the rectangle array, three light-emitting elements 20 are provided in each pixel P. Thus, the number of light-emitting elements 20 can be reduced by using the rectangle array as compared with the case of the Bayer array. Consequently, the flat area of the light-emitting region AB can be increased. Thus, the opening ratio of the light-emitting region AB can be improved.

The light-emitting element layer 2C and the color filter 5C according to the fourth embodiment described above can also improve the visual field angle characteristics.

### 1E. Fifth Embodiment

A fifth embodiment will be described. Note that, for the elements having the same functions as those of the fourth embodiment in each of the following examples, the reference signs used in the description of the fourth embodiment will be used and detailed description of each will be appropriately omitted.

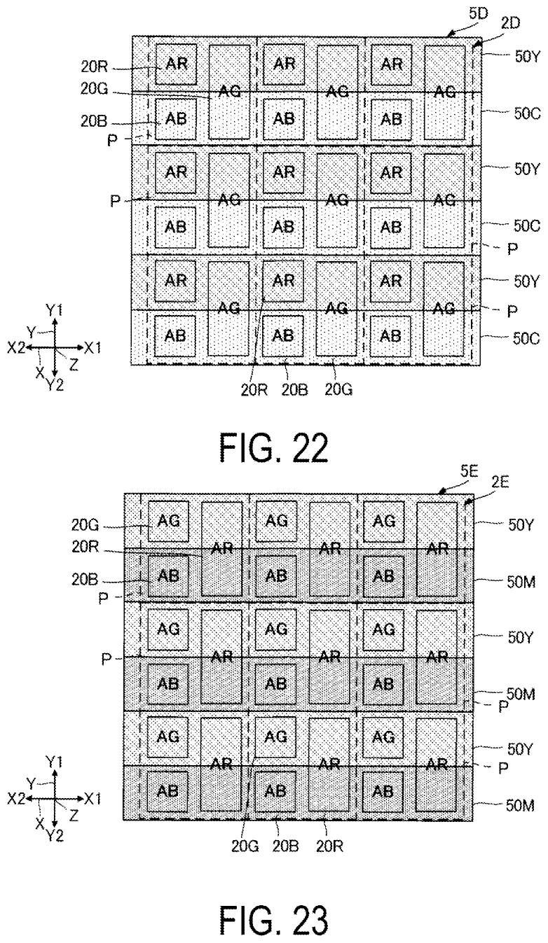

FIG. 22 is a schematic plan view illustrating an arrangement of a light-emitting element layer 2D and a color filter 5D according to the fifth embodiment. Hereinafter, regarding the light-emitting element layer 2D and the color filter 5D, items different from the light-emitting element layer 2C and the color filter 5C according to the fourth embodiment will be described, and description of the same items will be omitted.

As illustrated in FIG. 22, in the light-emitting element layer 2D, the direction in which the light-emitting region AR and the light-emitting region AB are aligned is different from the direction in which the light-emitting region AR and the light-emitting region AG are aligned, and the direction in which the light-emitting region AB and the light-emitting region AG are aligned. The direction in which the light-emitting region AR and the light-emitting region AG are aligned is the same as the direction in which the light-emitting region AB and the light-emitting region AG are aligned, and in the illustrated example, the direction is the X1 direction. The direction in which the light-emitting region AR and the light-emitting region AB are aligned is the Y2 direction. Further, in this embodiment, the area of the light-emitting region AG among the three light-emitting regions A is the largest. The light-emitting region AG is rectangular, and each of the light-emitting region AR and the light-emitting region AB is square.

In this embodiment, the light-emitting element 20R corresponds to the “first light-emitting element”, the light-emitting element 20B corresponds to the “second light-emitting element”, and the light-emitting element 20G corresponds to the “third light-emitting element”. Further, the light-emitting region AR corresponds to the “first light-emitting region”, the light-emitting region AB corresponds to the “second light-emitting region”, and the light-emitting region AG corresponds to the “third light-emitting region”. In addition, the red wavelength region corresponds to the “first wavelength region”, the blue wavelength region corresponds to the “second wavelength region”, and the green wavelength region corresponds to the “third wavelength region”.

The color filter 5D includes the plurality of yellow filters 50Y and the plurality of cyan filters 50C. The plurality of yellow filters 50Y and the plurality of cyan filters 50C are located on the same plane as each other. The plurality of yellow filters 50Y and the plurality of cyan filters 50C are arranged in a stripe shape. In the illustrated example, the yellow filter 50Y and the cyan filter 50C each have a long shape extending in the X1 direction in plan view. The plurality of yellow filters 50Y and the plurality of cyan filters 50C are arranged alternately in the Y2 direction.

In this embodiment, the yellow filter 50Y corresponds to the “first filter”, and the cyan filter 50C corresponds to the “second filter”. Note that the characteristics of the yellow filter 50Y are illustrated in FIG. 15. In addition, as in the second embodiment, as illustrated in FIG. 16, by using the two types of filters, the yellow filter 50Y and the cyan filter 50C, the color filter 5D can transmit light in the wavelength regions of red, green, and blue.

Further, as illustrated in FIG. 22, the light-emitting region AR overlaps the yellow filter 50Y in plan view. The light-emitting region AB overlaps the cyan filter 50C in plan view. In plan view, the light-emitting region AG has a portion overlapping the yellow filter 50Y and a portion overlapping the cyan filter 50C.

As described above, in this embodiment, the yellow filter 50Y and the cyan filter 50C are arranged as illustrated in FIG. 22 for the light-emitting element 20R, the light-emitting element 20G, and the light-emitting element 20B. In this embodiment as well, as in the fourth embodiment, by providing the two types of filters for the three types of light-emitting elements 20, the flat area of each of the filters can be increased as compared with the case in which the three types of filters corresponding to each of the three types of light-emitting elements 20 are provided. Consequently, it is possible to suppress the absorbing of light from each light-emitting element 20 by the filter.

Specifically, as illustrated in FIG. 22, the shape of the yellow filter 50Y in plan view is a long shape extending in the X1 direction. Consequently, light in the red wavelength region from the light-emitting region AR spreads in the X1 direction and the X2 direction and passes through the yellow filter 50Y. Similarly, the shape of the cyan filter 50C in plan view is a long shape extending in the X1 direction. Consequently, light in the blue wavelength region from the light-emitting region AB spreads in the X1 direction and the X2 direction and passes through the cyan filter 50C.

Further, light in the green wavelength region from the light-emitting region AG passes through the yellow filter 50Y and the cyan filter 50C. Consequently, light in the green wavelength region from the light-emitting region AG passes through the color filter 5D without being absorbed by the filter.

Therefore, in this embodiment as well, similar to the fourth embodiment, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced. In addition, the opening ratio for each sub-pixel P0 can be improved.

In this embodiment, as described above, the array of the light-emitting regions AR, AG, and AB is the rectangle array. Then, the yellow filter 50Y and the cyan filter 50C are aligned in the direction in which the light-emitting region AR and the light-emitting region AB are aligned. Since the yellow filter 50Y and the cyan filter 50C are arranged in this way, the yellow filter 50Y and the cyan filter 50C can be efficiently arranged. Consequently, the total number of the yellow filters 50Y and cyan filters 50C can be reduced, and thus each flat area of the yellow filters 50Y and the cyan filters 50C can be increased. Thus, it is possible to increase the spreading angle when light in the red wavelength region from the light-emitting region AR and light in the blue wavelength region from the light-emitting region AB pass through the color filter 5D.

The light-emitting element layer 2D and the color filter 5D according to the fifth embodiment described above can also improve the visual field angle characteristics.

### 1F. Sixth Embodiment

A sixth embodiment will be described. Note that, for the elements having the same functions as those of the fourth embodiment in each of the following examples, the reference signs used in the description of the fourth embodiment will be used and detailed description of each will be appropriately omitted.

FIG. 23 is a schematic plan view illustrating an arrangement of a light-emitting element layer 2E and a color filter 5E according to the sixth embodiment. Hereinafter, regarding the light-emitting element layer 2E and the color filter 5E, items different from the light-emitting element layer 2C and the color filter 5C according to the fourth embodiment will be described, and description of the same items will be omitted.

As illustrated in FIG. 23, in the light-emitting element layer 2E, the direction in which the light-emitting region AG and the light-emitting region AB are aligned is different from the direction in which the light-emitting region AG and the light-emitting region AR are aligned, and the direction in which the light-emitting region AB and the light-emitting region AR are aligned. The direction in which the light-emitting region AG and the light-emitting region AR are aligned is the same as the direction in which the light-emitting region AB and the light-emitting region AR are aligned, and in the illustrated example, the direction is the X1 direction. The direction in which the light-emitting region AG and the light-emitting region AB are aligned is the Y2 direction. Further, in this embodiment, the area of the light-emitting region AR among the three light-emitting regions A is the largest. The light-emitting region AR is rectangular, and each of the light-emitting region AG and the light-emitting region AB is square.

In this embodiment, the light-emitting element 20G corresponds to the “first light-emitting element”, the light-emitting element 20B corresponds to the “second light-emitting element”, and the light-emitting element 20R corresponds to the “third light-emitting element”. Further, the light-emitting region AG corresponds to the “first light-emitting region”, the light-emitting region AB corresponds to the “second light-emitting region”, and the light-emitting region AR corresponds to the “third light-emitting region”. In addition, the green wavelength region corresponds to the “first wavelength region”, the blue wavelength region corresponds to the “second wavelength region”, and the red wavelength region corresponds to the “third wavelength region”.

The color filter 5E includes the plurality of yellow filters 50Y and the plurality of magenta filters 50M. The plurality of yellow filters 50Y and the plurality of magenta filters 50M are located on the same plane as each other. The plurality of yellow filters 50Y and the plurality of magenta filters 50M are arranged in a stripe shape. In the illustrated example, the yellow filter 50Y and the magenta filter 50M each have a long shape extending in the X1 direction in plan view. The plurality of yellow filters 50Y and the plurality of magenta filters 50M are arranged alternately in the Y2 direction.

In this embodiment, the yellow filter 50Y corresponds to the “first filter”, and the magenta filter 50M corresponds to the “second filter”. In addition, as in the third embodiment, as illustrated in FIG. 18, by using the two types of filters, the yellow filter 50Y and the magenta filter 50M, the color filter 5E can transmit light in the wavelength regions of red, green, and blue.

Further as illustrated in FIG. 23, the light-emitting region AG overlaps the yellow filter 50Y in plan view. The light-emitting region AB overlaps the magenta filter 50M in plan view. In plan view, the light-emitting region AR has a portion overlapping the yellow filter 50Y and a portion overlapping the magenta filter 50M.

As described above, in this embodiment, the yellow filter 50Y and the magenta filter 50M are arranged as illustrated in FIG. 23 for the light-emitting element 20R, the light-emitting element 20G, and the light-emitting element 20B. In this embodiment as well, as in the fourth embodiment, by providing the two types of filters for the three types of light-emitting elements 20, the flat area of each of the filters can be increased as compared with the case in which the three types of filters corresponding to each of the three types of light-emitting elements 20 are provided. Consequently, it is possible to suppress the absorbing of light from each light-emitting element 20 by the filter.

Specifically, as illustrated in FIG. 23, the shape of the yellow filter 50Y in plan view is a long shape extending in the X1 direction. Consequently, light in the green wavelength region from the light-emitting region AG spreads in the X1 direction and the X2 direction and passes through the yellow filter 50Y. Similarly, the shape of the magenta filter 50M in plan view is a long shape extending in the X1 direction. Consequently, light in the blue wavelength region from the light-emitting region AB spreads in the X1 direction and the X2 direction and passes through the magenta filter 50M.

Further, light in the red wavelength region from the light-emitting region AR passes through the yellow filter 50Y and the magenta filter 50M. Consequently, light in the red wavelength region from the light-emitting region AR passes through the color filter 5E without being absorbed by the filter.

Therefore, in this embodiment as well, similar to the fourth embodiment, it is suppressed that the spreading angle of the light becomes small because the light from the light-emitting element 20 is absorbed by the filter. Thus, even when the width of the sub-pixel P0 is reduced or the density of the sub-pixel P0 is increased, it is possible to suppress the possibility that the visual field angle characteristics are reduced.

In this embodiment, as described above, the array of the light-emitting regions AR, AG, and AB is the rectangle array. Then, the yellow filter 50Y and the magenta filter 50M are aligned in the direction in which the light-emitting region AG and the light-emitting region AB are aligned. Since the yellow filter 50Y and the magenta filter 50M are arranged in this way, the yellow filter 50Y and the magenta filter 50M can be efficiently arranged. Consequently, the total number of yellow filters 50Y and magenta filters 50M can be reduced, and thus each flat area of the yellow filters 50Y and the magenta filters 50M can be increased. Thus, it is possible to increase the spreading angle when light in the green wavelength region from the light-emitting region AG and light in the blue wavelength region from the light-emitting region AB pass through the color filter 5E.

The light-emitting element layer 2E and the color filter 5E according to the sixth embodiment described above can also improve the visual field angle characteristics.

### 1G. Modification Example

Each of the exemplary embodiments exemplified in the above can be variously modified. Specific modification aspects applied to each of the embodiments described above are exemplified below. Two or more aspects freely selected from exemplifications below can be appropriately used in combination as long as mutual contradiction does not arise.

In each embodiment, the light-emitting element 20 includes the optical resonance structure 29 having a different resonance wavelength for each color, but the optical resonance structure 29 may not be included. Further, the light-emitting element layer 2 may include, for example, a partition wall that partitions the organic layer 24 for each light-emitting element 20. Further, in the light-emitting element 20, each sub-pixel P0 may include a different light emitting material. Additionally, the pixel electrode 23 may have light reflectivity. In this case, the reflection layer 21 may be omitted. In addition, although the common electrode 25 is common to the plurality of light-emitting elements 20, a separate cathode may be provided for each light-emitting element 20.

In the first embodiment, the filters included in the color filter 5 are arranged so as to be in contact with each other, but a so-called black matrix may be interposed between the filters included in the color filter 5. In addition, the filters included in the color filter 5 may have portions that overlap each other. The same applies to the other embodiments.

The array of the light-emitting regions A is not limited to the Bayer array and the rectangle array, and may be, for example, a delta array or a stripe array.

The “electro-optical device” is not limited to the organic EL device, and may be an inorganic EL device using an inorganic material or a μLED device.

### 2. Electronic Apparatus

The electro-optical device 100 of the above-described embodiments is applicable to various electronic apparatuses.

2-1. Head-Mounted Display

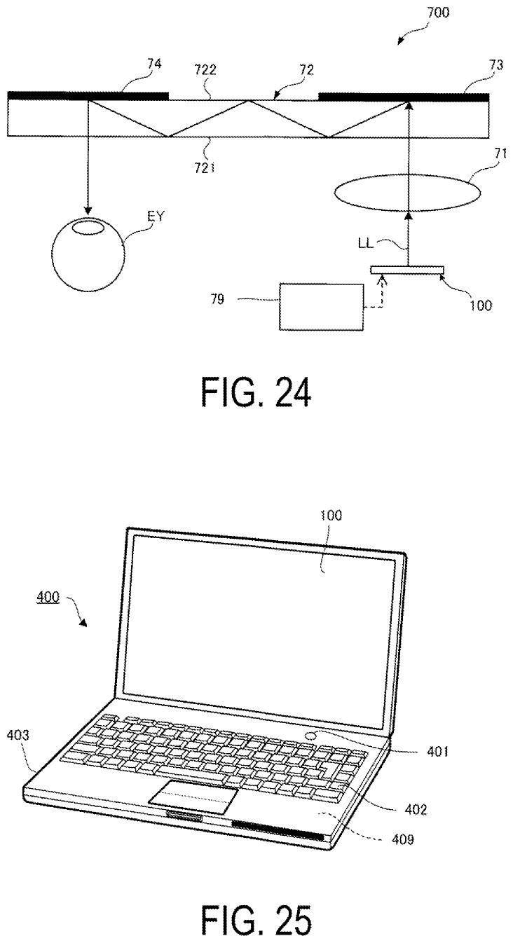

FIG. 24 is a plan view schematically illustrating a part of a virtual image display device 700 as an example of an electronic apparatus. The virtual image display device 700 illustrated in FIG. 24 is a head-mounted display (HMD) mounted on the observer's head and displays an image. The virtual image display device 700 includes the above-mentioned electro-optical device 100, a collimator 71, a light guide 72, a first reflection-type volume hologram 73, a second reflection-type volume hologram 74, and a control unit 79. Note that light emitted from the electro-optical device 100 is emitted as image light LL.

The control unit 79 includes, for example, a processor and a memory, and controls the operation of the electro-optical device 100. The collimator 71 is disposed between the electro-optical device 100 and the light guide 72. The collimator 71 collimates the light emitted from the electro-optical device 100. The collimator 71 is constituted of a collimating lens or the like. The light collimated by the collimator 71 is incident on the light guide 72.

The light guide 72 has a flat plate shape, and is disposed so as to extend in a direction intersecting a direction of light incident via the collimator 71. The light guide 72 reflects and guides light therein. A light incident port on which light is incident and a light emission port from which light is emitted are provided at a surface 721 of the light guide 72 facing the collimator 71. The first reflection-type volume hologram 73 as a diffractive optical element and the second reflection-type volume hologram 74 as a diffractive optical element are disposed on a surface 722 of the light guide 72 opposite to the surface 721. The second reflection-type volume hologram 74 is provided closer to the light emission port side than the first reflection-type volume hologram 73. The first reflection-type volume hologram 73 and the second reflection-type volume hologram 74 have interference fringes corresponding to a predetermined wavelength region, and diffract and reflect light in the predetermined wavelength region.

In the virtual image display device 700 having such a configuration, the image light LL incident on the light guide 72 from the light incident port travels while being repeatedly reflected, and is guided to an eye EY of the observer from the light emission port, and thus the observer can observe an image constituted of a virtual image formed by the image light LL.

The virtual image display device 700 includes the above-described electro-optical device 100. The above-described electro-optical device 100 has excellent visual field angle characteristics and has high quality. Consequently, the virtual image display device 700 with high display quality can be provided by including the electro-optical device 100.

2-2. Personal Computer

FIG. 25 is a perspective view illustrating a personal computer 400 as an example of the electronic apparatus in the present disclosure. The personal computer 400 illustrated in FIG. 25 includes the electro-optical device 100, a main body 403 provided with a power switch 401 and a keyboard 402, and a control unit 409. The control unit 409 includes, for example, a processor and a memory, and controls the operation of the electro-optical device 100. As for the personal computer 400, the above-described electro-optical device 100 has excellent visual field angle characteristics and has high quality. Consequently, by providing the electro-optical device 100, the personal computer 400 with high display quality can be provided.

Note that examples of the “electronic apparatus” including the electro-optical device 100 include, in addition to the virtual image display device 700 illustrated in FIG. 24 and the personal computer 400 illustrated in FIG. 25, apparatuses used near the eyes such as a digital scope, digital binoculars, a digital still camera, and a video camera. Further, the “electronic apparatus” including the electro-optical device 100 is applied as a mobile phone, a smartphone, a personal digital assistant (PDA), a car navigation device, and a vehicle-mounted display unit. Furthermore, the “electronic apparatus” including the electro-optical device 100 is applied as a lighting apparatus for illuminating light.

The present disclosure was described above based on the illustrated embodiments. However, the present disclosure is not limited thereto. In addition, the configuration of each component of the present disclosure may be replaced with any configuration that exerts the equivalent functions of the above-described embodiments, and to which any configuration may be added. Further, any configuration may be combined with each other in the above-described embodiments of the present disclosure.

What is claimed is:

1. An electro-optical device comprising:
a first light-emitting element configured to emit light in a first wavelength region;
a second light-emitting element configured to emit light in a second wavelength region different from the first wavelength region;
a third light-emitting element configured to emit light in a third wavelength region different from the second wavelength region;
a first filter configured to transmit light in the first wavelength region and light in the third wavelength region and absorb light in the second wavelength region; and
a second filter configured to transmit light in the second wavelength region and light in the third wavelength region and absorb light in the first wavelength region, wherein
the third light-emitting element has a portion overlapping the first filter and a portion overlapping the second filter in plan view.

2. The electro-optical device according to claim 1, wherein
the first light-emitting element overlaps the first filter in plan view, and
the second light-emitting element overlaps the second filter in plan view.

3. The electro-optical device according to claim 1, wherein
the third wavelength region is a wavelength region including a shorter wavelength than the second wavelength region, and
the second wavelength region is a wavelength region including a shorter wavelength than the first wavelength region.

4. The electro-optical device according to claim 1, wherein
the first light-emitting element, the second light-emitting element, and the third light-emitting element have optical resonance structures that differ from one another.

5. The electro-optical device according to claim 1, further comprising:
a fourth light-emitting element configured to emit light in the third wavelength region, wherein
an array of the first light-emitting element, the second light-emitting element, the third light-emitting element, and the fourth light-emitting element is a Bayer array, and
a direction in which the first filter and the second filter are aligned intersects a direction in which the third light-emitting element and the fourth light-emitting element are aligned.

6. The electro-optical device according to claim 1, wherein
an array of the first light-emitting element, the second light-emitting element, and the third light-emitting element is a rectangle array, and
the first filter and the second filter are aligned in a direction in which the first light-emitting element and the second light-emitting element are aligned.

7. An electronic apparatus comprising:
the electronic-optical device according to claim 1; and
a control unit configured to control operation of the electro-optical device.
